(19) United States
(12) Patent Application Publication
(10) Pub. No.: US 2026/0156911 A1
(43) Pub. Date: Jun. 4, 2026

(54) SEMICONDUCTOR STRUCTURE AND METHOD FOR FORMING THE SAME

(71) Applicant: Taiwan Semiconductor Manufacturing Co., Ltd., Hsinchu (TW)

(72) Inventors: Shao-Tse Huang, Hsinchu (TW); Hsin Yang Hung, New Taipei (TW); Jin-Hao Jhang, Chubei (TW); Wei-De Ho, Hsinchu (TW)

(21) Appl. No.: 19/055,112

(22) Filed: Feb. 17, 2025

Related U.S. Application Data
(60) Provisional application No. 63/727,467, filed on Dec. 3, 2024.

(51) Int. Cl. H10D 84/01; H10D 84/85

(52) U.S. Cl. CPC H10D 84/0188; H10D 84/017; H10D 84/0186; H10D 84/851; H10D 84/856

(57) ABSTRACT

A method for forming a semiconductor structure is provided. The method includes forming an isolation structure to surround a lower portion of an active region, forming a gate stack across the active region, forming a trench through the gate stack, forming a conductive feature in the trench, depositing a metal material on a backside surface of the isolation structure, and planarizing the metal material, the isolation structure, the conductive feature, and the lower portion of the active region.

### PRIORITY CLAIM

This application claims the benefit of U.S. Provisional Application No. 63/727,467 filed on Dec. 3, 2024 and entitled “CEFT DEVICE AND METHOD FOR FORMING THE SAME,” which is incorporated herein by reference.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary field effect transistors (CFETs) have been introduced. In a CFET structure, nMOS and pMOS devices are stacked on top of each other, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A, 2D, 2E, 2F, 2G, 2H and 2N are layouts (top views) illustrating the formation of a semiconductor structure at various cross-sectional views, in accordance with some embodiments.

FIGS. 2A-1, 2A-2 and 2A-3 are cross-sectional views illustrating the formation of a semiconductor structure at one of the intermediate stages corresponding to line X-X, line Y1-Y1 and line Y2-Y2 of FIG. 2A, in accordance with some embodiments of the disclosure.

FIGS. 2B-1, 2B-2 and 2B-3 are cross-sectional views illustrating the formation of a semiconductor structure at one of the intermediate stages corresponding to line X-X, line Y1-Y1 and line Y2-Y2 of FIG. 2A, in accordance with some embodiments of the disclosure.

FIGS. 2C-1, 2C-2 and 2C-3 are cross-sectional views illustrating the formation of a semiconductor structure at one of the intermediate stages corresponding to line X-X, line Y1-Y1 and line Y2-Y2 of FIG. 2A, in accordance with some embodiments of the disclosure.

FIGS. 2D-1, 2D-2 and 2D-3 are cross-sectional views illustrating the formation of a semiconductor structure at one of the intermediate stages corresponding to line X-X, line Y1-Y1 and line Y2-Y2 of FIG. 2D, in accordance with some embodiments of the disclosure.

FIGS. 2E-1, 2E-2 and 2E-3 are cross-sectional views illustrating the formation of a semiconductor structure at one of the intermediate stages corresponding to line X-X, line Y1-Y1 and line Y2-Y2 of FIG. 2E, in accordance with some embodiments of the disclosure.

FIGS. 2F-1, 2F-2 and 2F-3 are cross-sectional views illustrating the formation of a semiconductor structure at one of the intermediate stages corresponding to line X-X, line Y1-Y1 and line Y2-Y2 of FIG. 2F, in accordance with some embodiments of the disclosure.

FIGS. 2G-1, 2G-2 and 2G-3 are cross-sectional views illustrating the formation of a semiconductor structure at one of the intermediate stages corresponding to line X-X, line Y1-Y1 and line Y2-Y2 of FIG. 2G, in accordance with some embodiments of the disclosure.

FIGS. 2H-1, 2H-2 and 2H-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2I-1, 2I-2 and 2I-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2J-1, 2J-2 and 2J-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2K-1, 2K-2 and 2K-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2L-1, 2L-2 and 2L-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2M-1, 2M-2 and 2M-3 are cross-sectional views illustrating the formation of a semiconductor structure at one of the intermediate stages corresponding to line X-X, line Y1-Y1 and line Y2-Y2 of FIG. 2H, in accordance with some embodiments of the disclosure.

FIGS. 2N-1, 2N-2, 2N-3 and 2N-4 are cross-sectional views illustrating the formation of a semiconductor structure at one of the intermediate stages corresponding to line X-X, line Y1-Y1, line Y2-Y2 and line Y3-Y3 of FIG. 2N, in accordance with some embodiments of the disclosure.

FIGS. 3A-1, 3A-2, 3A-3 and 3A-4 are cross-sectional views illustrating the formation of a semiconductor structure at one of the intermediate stages corresponding to line X-X, line Y1-Y1, line Y2-Y2 and line Y3-Y3 of FIG. 2N, in accordance with some embodiments of the disclosure.

FIGS. 3B-1, 3B-2, 3B-3 and 3B-4 are cross-sectional views illustrating the formation of a semiconductor structure at one of the intermediate stages corresponding to line X-X, line Y1-Y1, line Y2-Y2 and line Y3-Y3 of FIG. 2N, in accordance with some embodiments of the disclosure.

FIGS. 4A-1, 4A-2, 4A-3 and 4A-4 are cross-sectional views illustrating the formation of a semiconductor structure at one of the intermediate stages corresponding to line X-X, line Y1-Y1, line Y2-Y2 and line Y3-Y3 of FIG. 2N, in accordance with some embodiments of the disclosure.

FIGS. 4B-1, 4B-2, 4B-3 and 4B-4 are cross-sectional views illustrating the formation of a semiconductor structure at one of the intermediate stages corresponding to line X-X, line Y1-Y1, line Y2-Y2 and line Y3-Y3 of FIG. 2N, in accordance with some embodiments of the disclosure.

FIGS. 5-1, 5-2, 5-3 and 5-4 are a modification of the semiconductor structure of FIG. 4N-1, 4N-2, 4N-3 and 4N-4, in accordance with some embodiments of the disclosure.

FIGS. 6A, 6B and 6C are various modifications of the semiconductor structure of FIG. 2N-3, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In 3D vertical stacked CFET (Complementary FET) design, the implementation of backside routing connections with Vertical Local Interconnect (VLI) features allows for enhanced routing feasibility and enables significant speed and density improvement. The VLI features are configured to electrically connect the source/drain terminal of the top transistor (TT) to the source/drain terminal of the bottom transistor (BT), and the formation of the VLI features can be integrated into CMOS manufacturing processes.

Embodiments of semiconductor structures and methods for forming the same are provided. The semiconductor structures may include a complementary field-effect transistor (CFET) device with a vertical local interconnect feature. A first planarization process for removing the silicon substrate and a second planarization process for thinning down the semiconductor components (e.g., the fin element, the STI feature, the VLI feature, etc.) are sequentially performed. The embodiments utilize metal material as a CMP overburn material. Due to high polishing selectivity between the metal material and the dielectric material, the bulk polishing step of the second planarization process may be stopped when the isolation structure is exposed, which may prevent the underlying VLI feature from protruding from the isolation structure. Therefore, the backside of the semiconductor structure may maintain a substantially flat surface topography after the buffer polishing step of the second planarization process, and the final height of these semiconductor components can be precisely controlled. The manufacturing yield and reliability of the resulting semiconductor device may be improved.

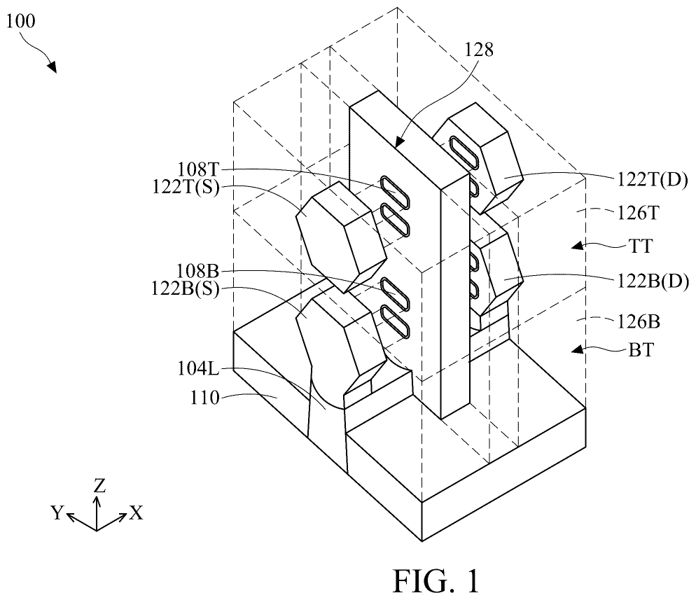

FIG. 1 is a perspective view of a semiconductor structure 100, in accordance with some embodiments.

The semiconductor structure 100 includes a fin element 104L, an isolation structure 110 surrounding the fin element 104L, a bottom transistor BT above the fin element 104L, and a top transistor TT directly above the bottom transistor BT, in accordance with some embodiments. Both the top transistor TT and the bottom transistor BT are nanostructure transistors such as GAA transistors, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate. The Y-axis is transverse (e.g., substantially perpendicular) to the X-axis. The Z-axis is generally oriented along the vertical direction that is perpendicular to the main surface of the substrate (or the X-Y plane).

In some embodiments, the bottom transistor BT is a p-channel FET, and the top transistor TT is an n-channel FET. In some other embodiments, the bottom transistor BT is an n-channel FET, and the top transistor TT is a p-channel FET. The semiconductor structure 100 may be used to form STD cells e.g., CMOS inverter, NAND, NOR, AND, OR, Flip-Flop, and/or SCAN cell regions, and/or memory cells such as SRAM.

The bottom transistor BT includes a plurality of nanostructures 108B, bottom source/drain features 122B (including 122B(S) for the source terminal and 122B (D) for the drain terminal) adjoining the nanostructures 108B, and the bottom portion of a gate stack 128 wrapped around the nanostructures 108B, in accordance with some embodiments. The top transistor TT includes a plurality of nanostructures 108T, top source/drain features 122T (including the 122T(S) for the source terminal and 122T (D) for the drain terminal) adjoining the nanostructures 108T, and the top portion of the gate stack 128 wrapped around the nanostructures 108T, in accordance with some embodiments.

The interlayer dielectric layers 126T and 126B are formed to cover the top source/drain features 122T and the bottom source/drain features 122B, respectively. The top source/drain features 122T and the bottom source/drain features 122B are electrically isolated from each other by the interlayer dielectric layer 126B, in accordance with some embodiments.

The nanostructures 108B/108T extend between the source/drain features 122B/122T in the X direction, in accordance with some embodiments. The nanostructures 108B and 108T function as the channels of the transistors BT and TT, in accordance with some embodiments. Although two nanostructures 108B and two nanostructures 108T are shown in FIG. 1, the number is not limited to two, and can be one or three, and is less than 10. The X direction may also be referred to as the channel-extending direction. The current of the resulting semiconductor device (i.e., nanostructure transistor) flows in the X direction through the channels. It is noted that in the present disclosure, source/drain region(s) or source/drain feature(s) may refer to a source or a drain, individually or collectively dependent upon the context.

The gate stack 128 is formed with longitudinal axes parallel to the Y direction, extends across the fin element 104L and the isolation structure 110, and surrounds the nanostructures 108B and 108T, in accordance with some embodiments. The Y direction may also be referred to as a gate-routing direction, in accordance with some embodiments. In some embodiments, the top portion of the gate stack 128 for the top transistor TT is physically connected to the bottom portion of the gate stack 128 for the bottom transistor BT. In some embodiments, the top portion of the gate stack 128 for the top transistor TT is electrically connected to the bottom portion of the gate stack 128 for the bottom transistor BT. In some other embodiments, the top portion of the gate stack 128 for the top transistor TT is physically and electrically isolated from the bottom portion of the gate stack 128 for the bottom transistor BT.

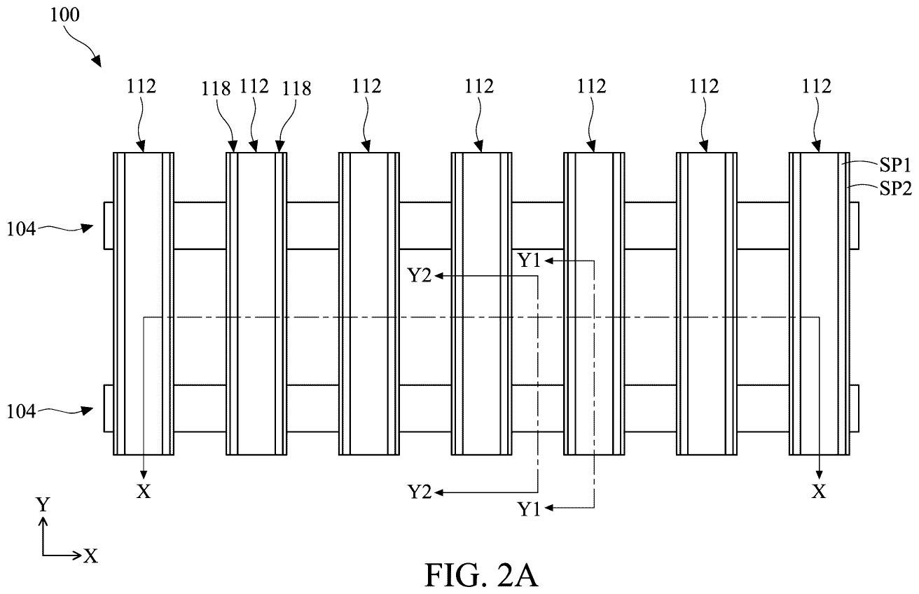

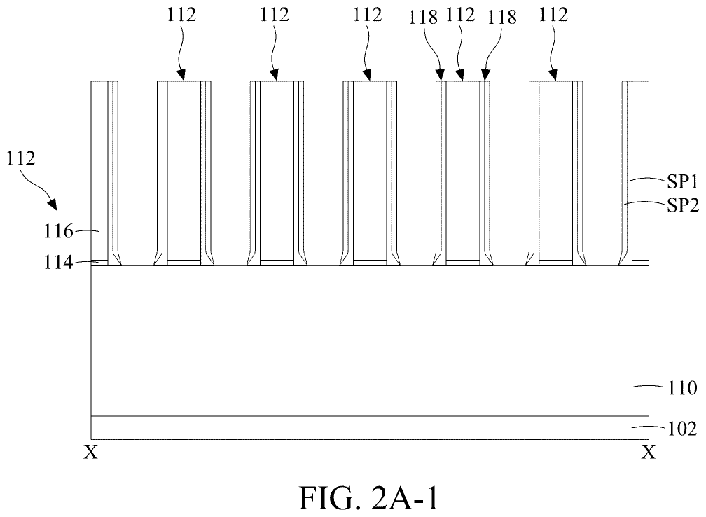

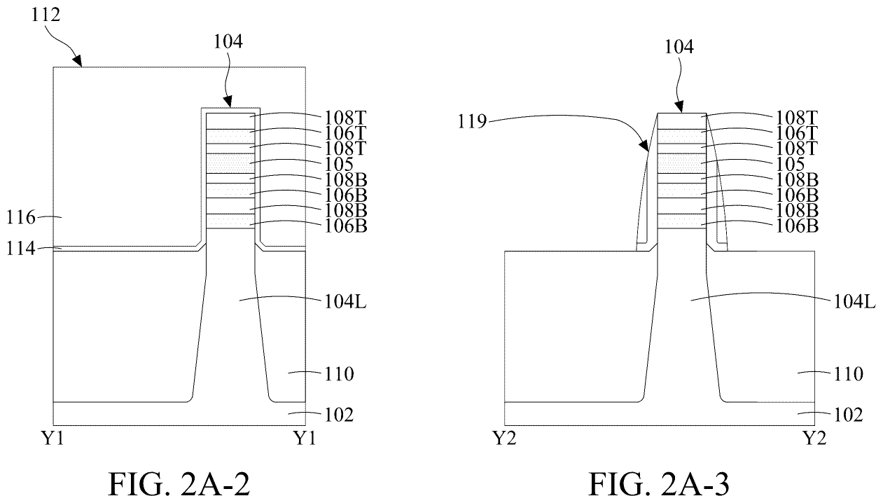

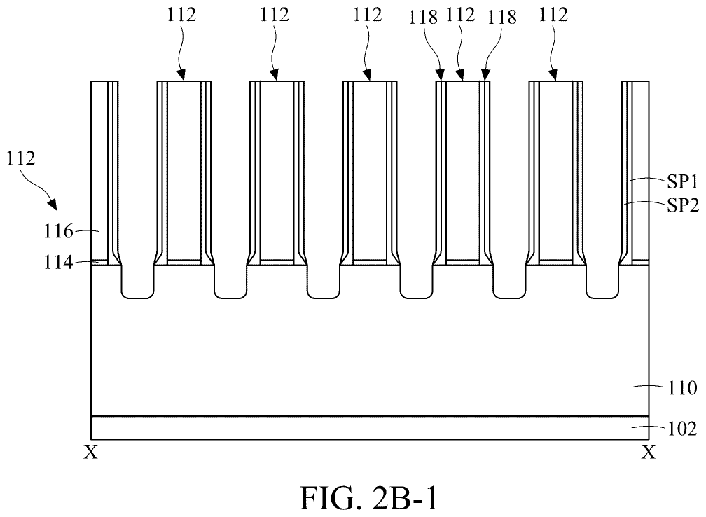

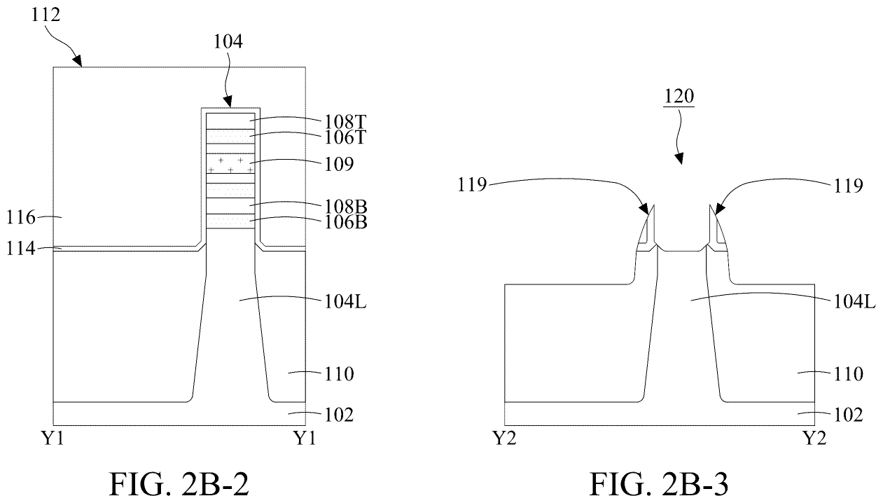

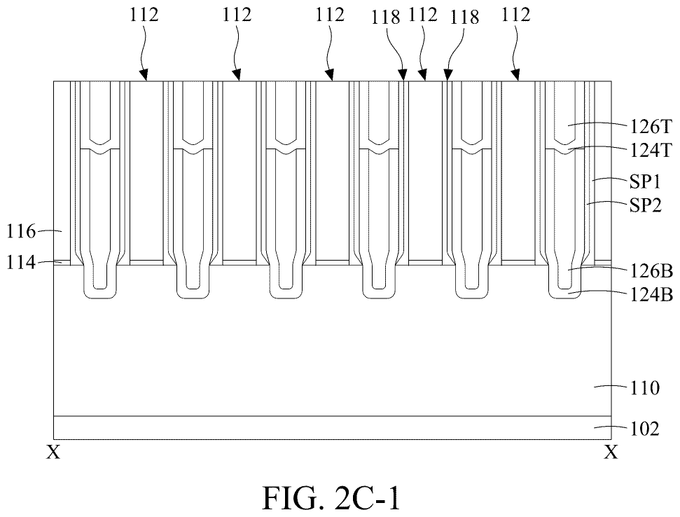

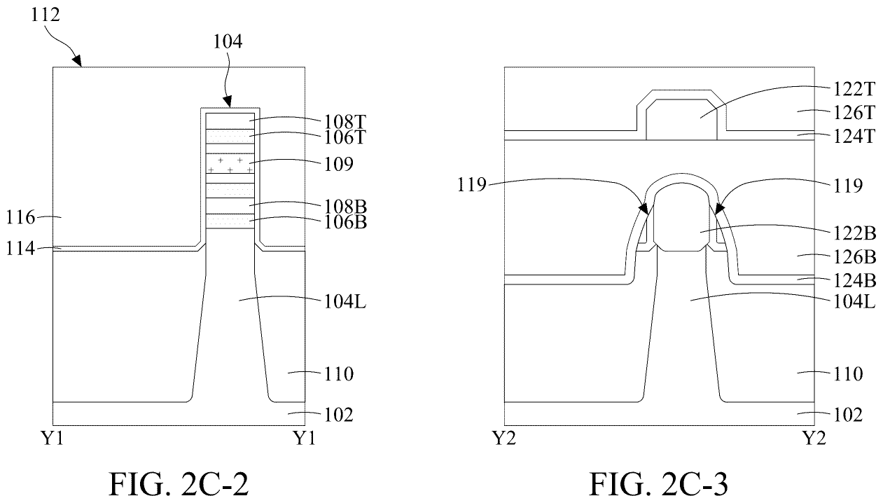

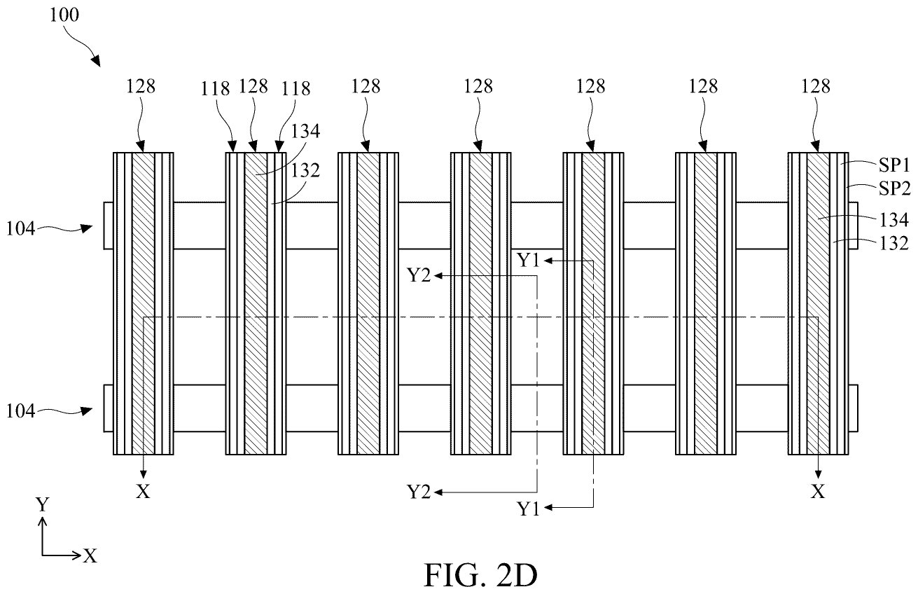

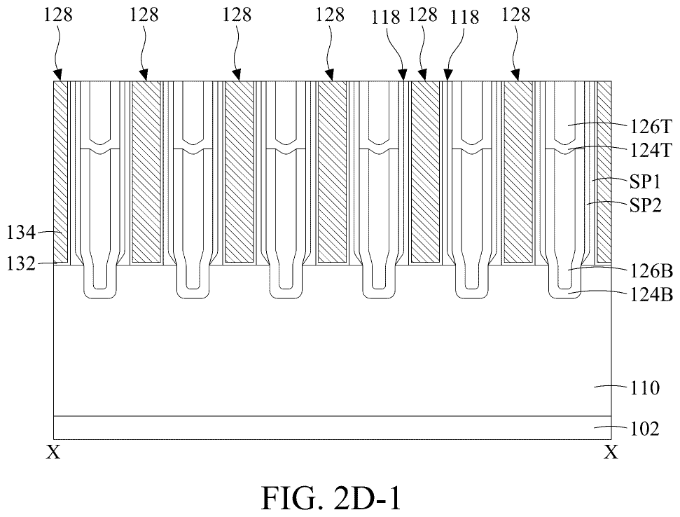

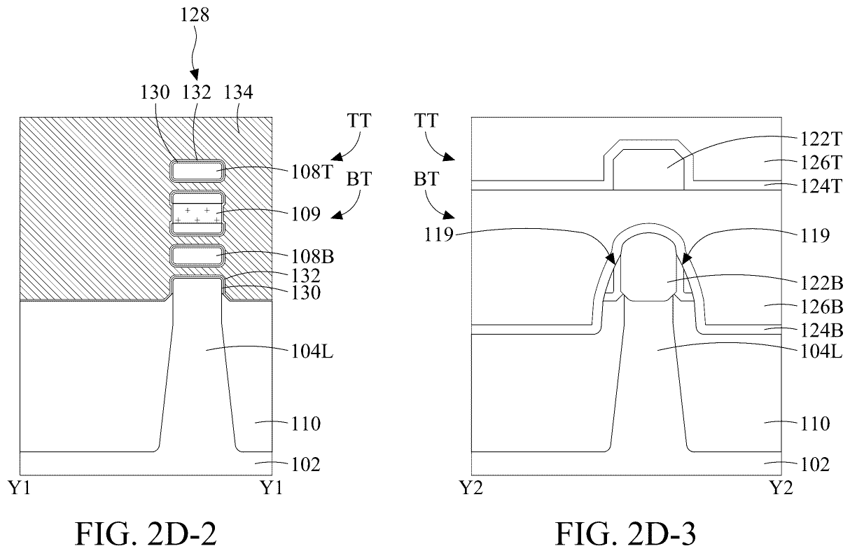

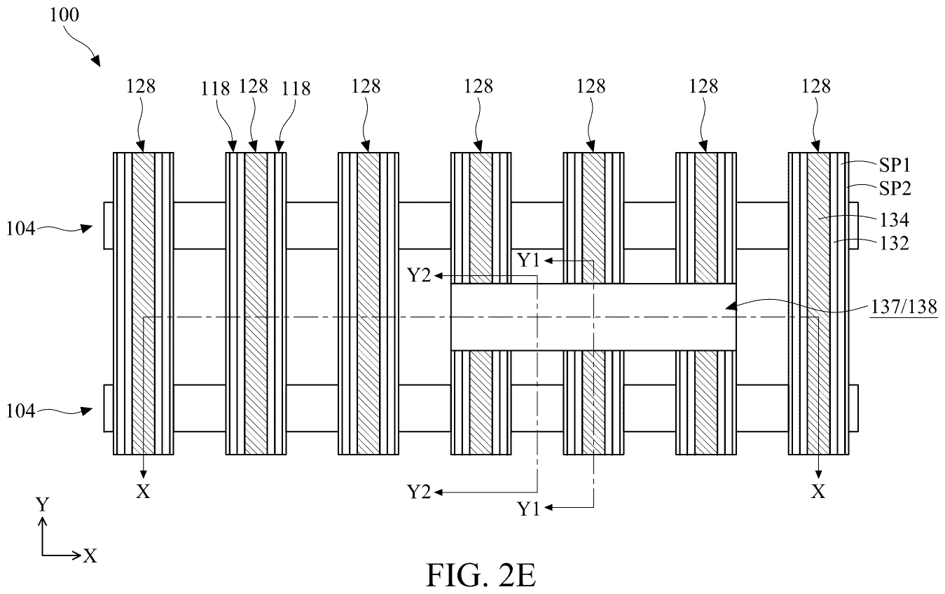

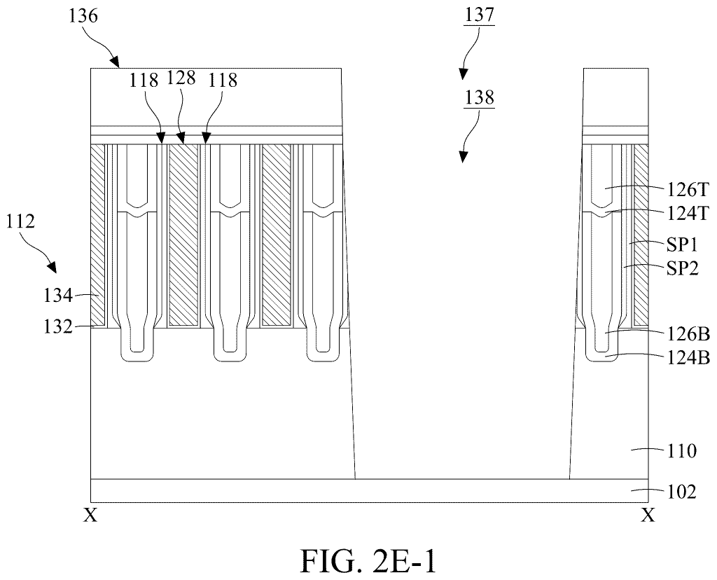

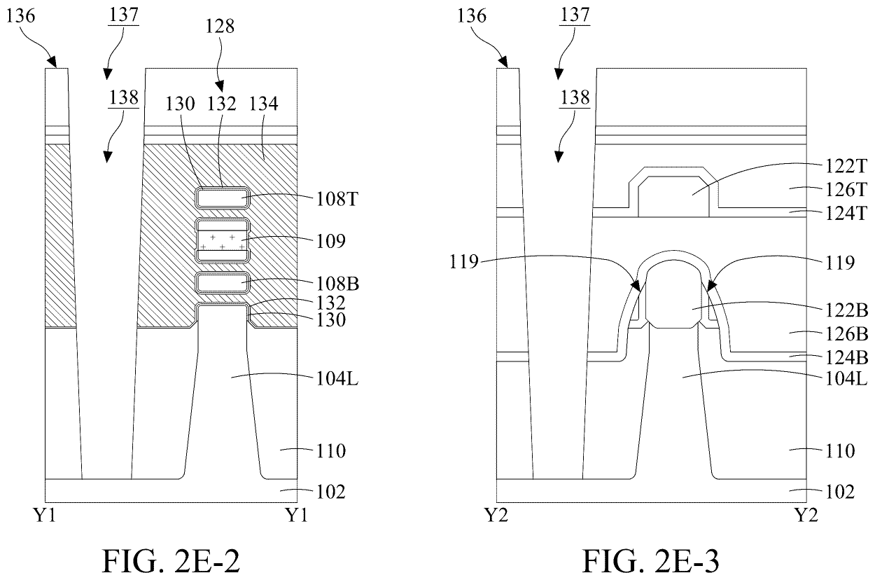

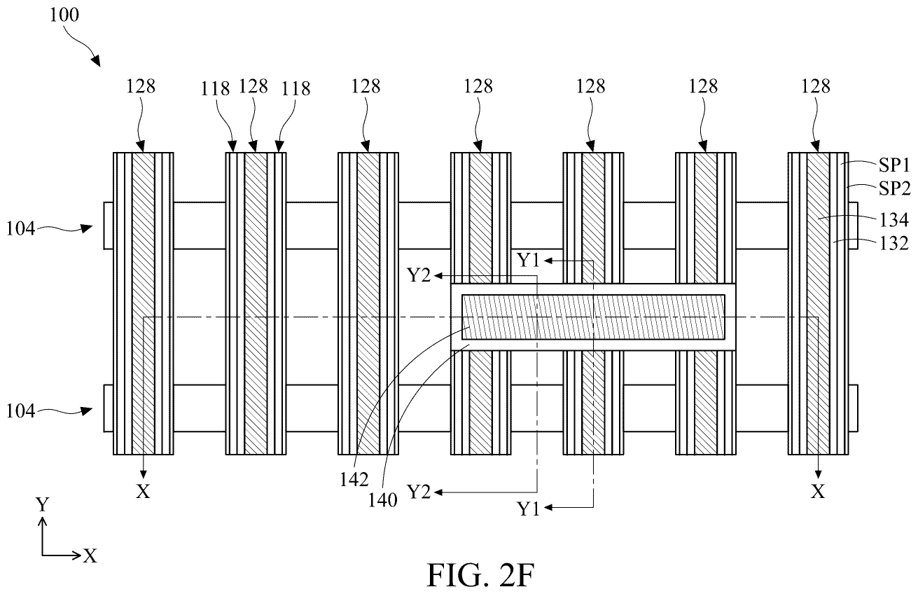

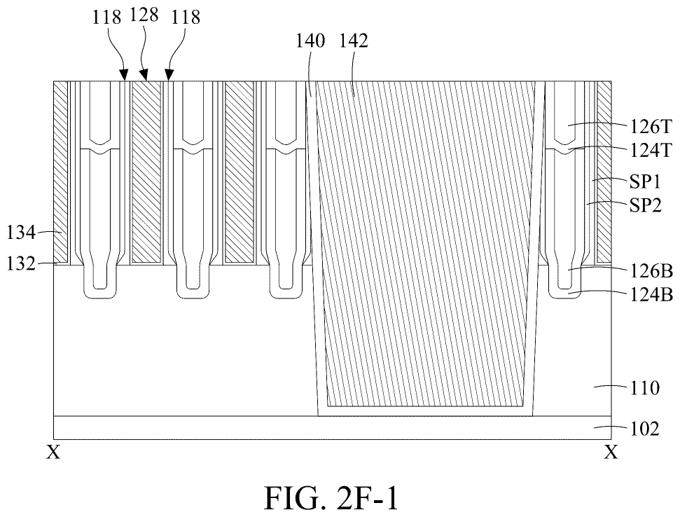

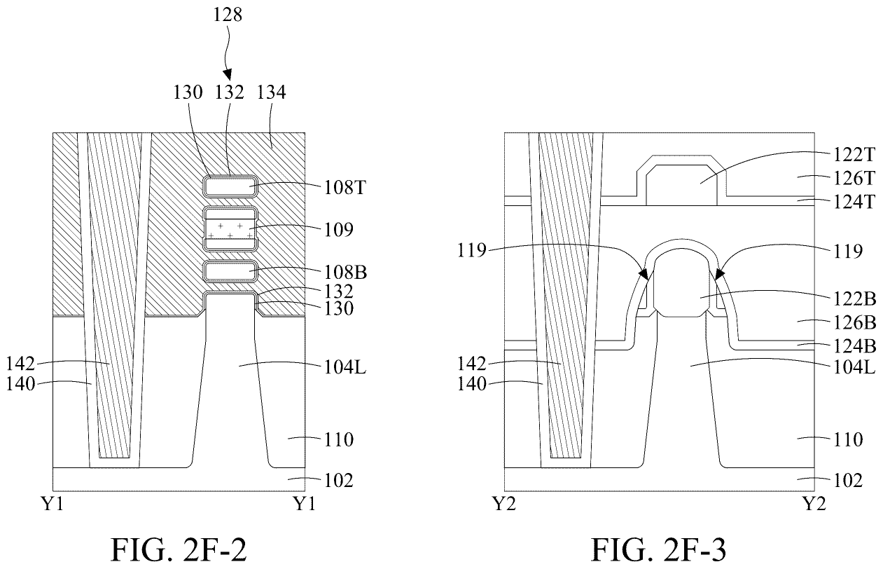

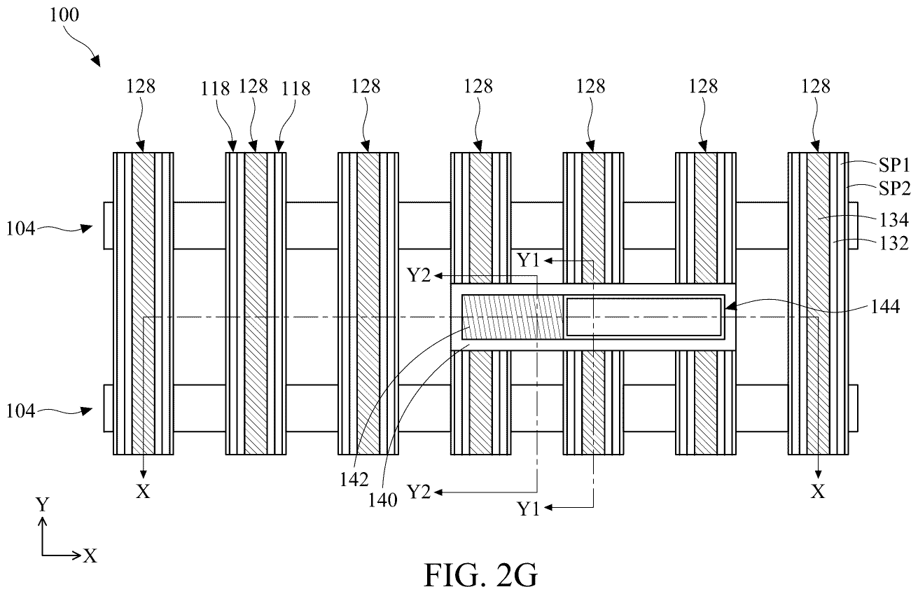

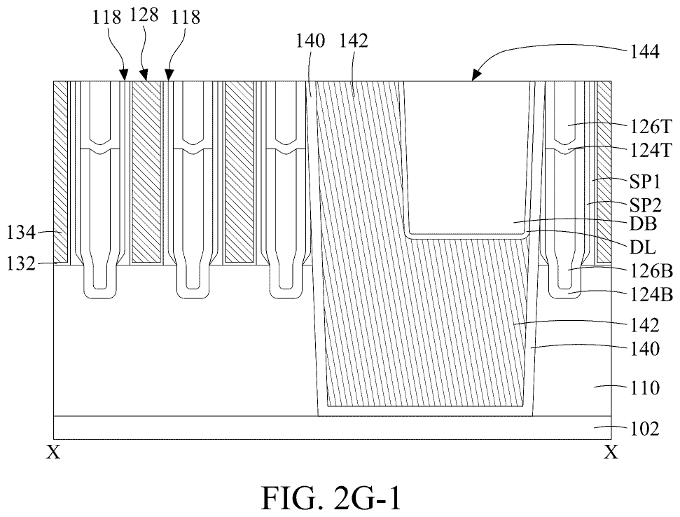

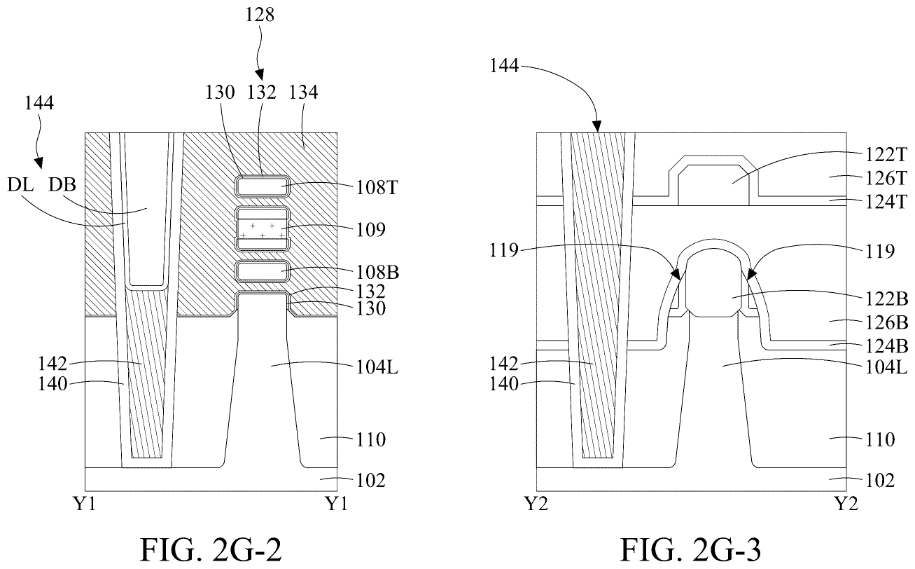

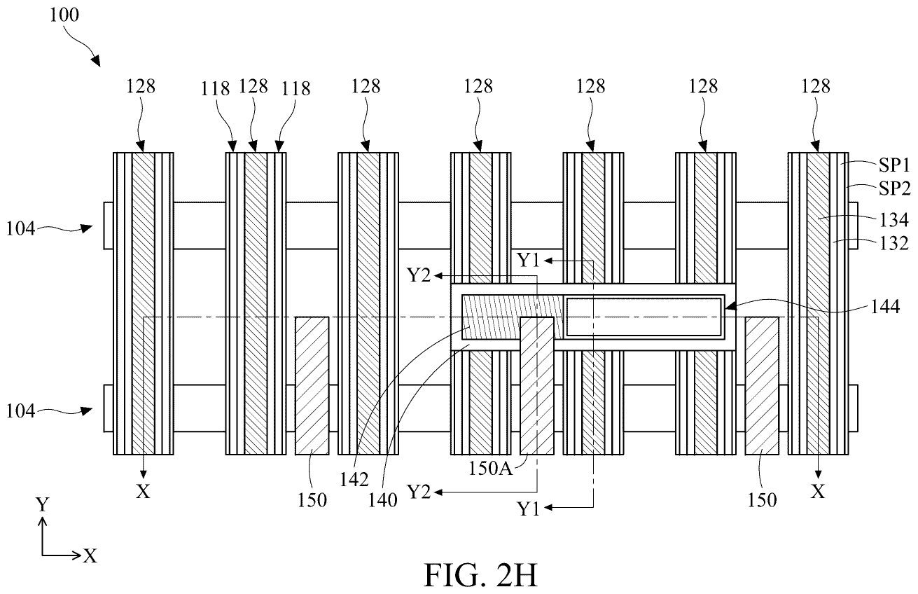

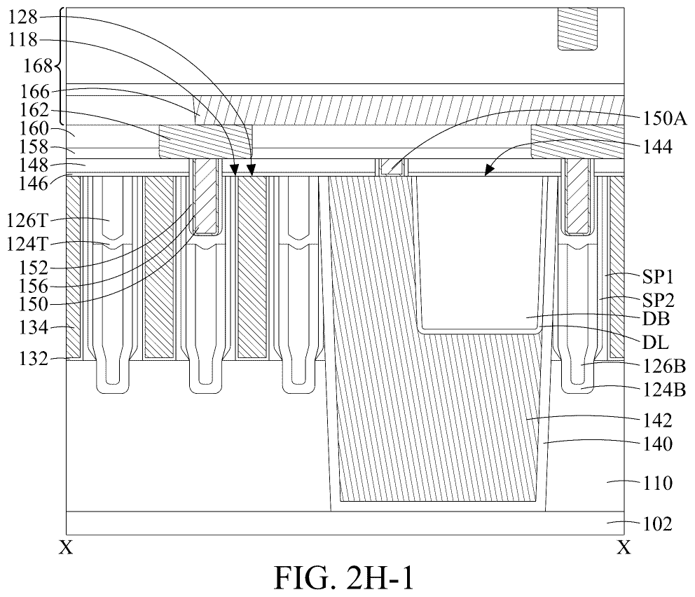

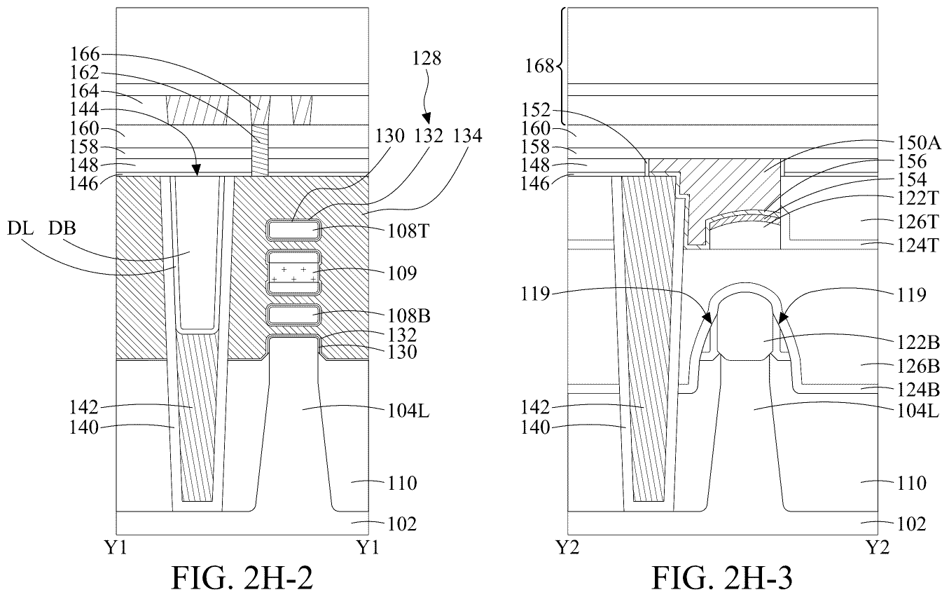

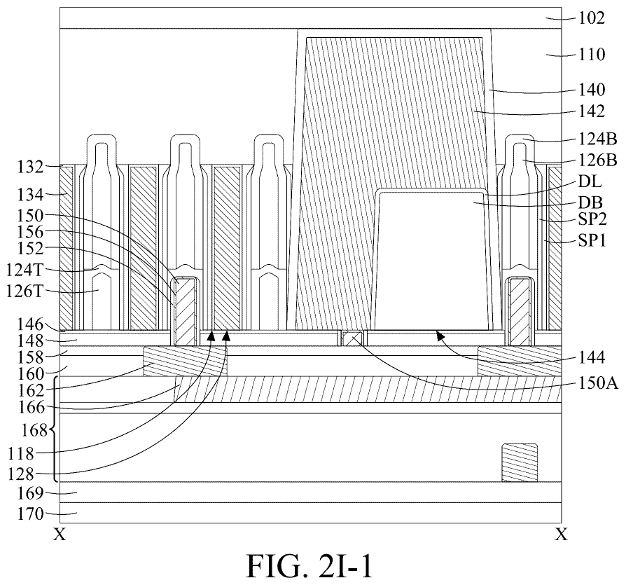

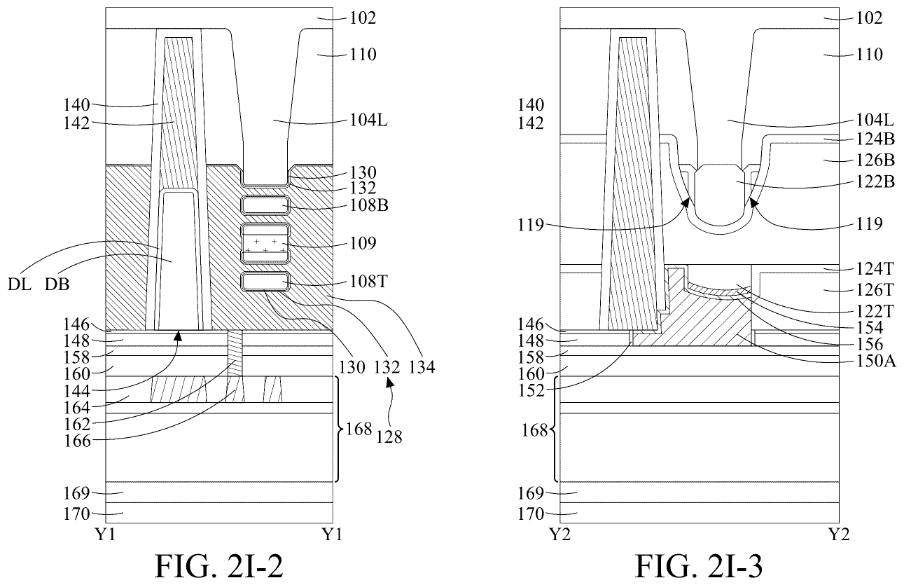

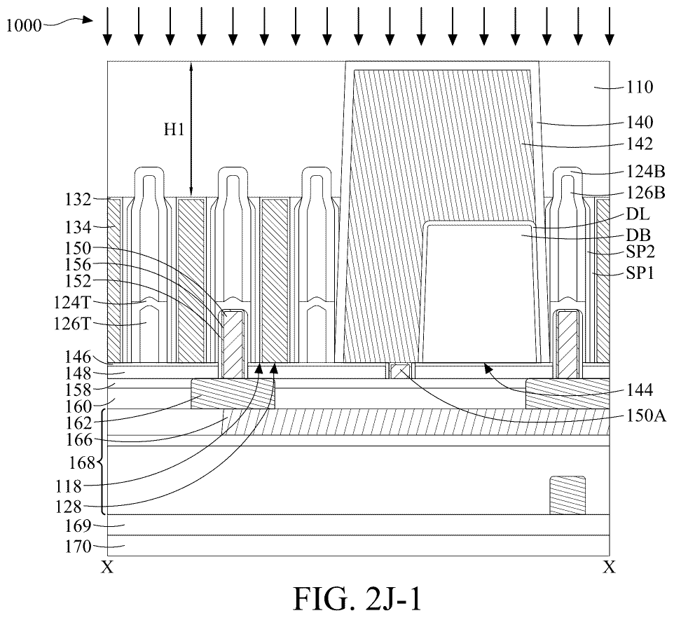

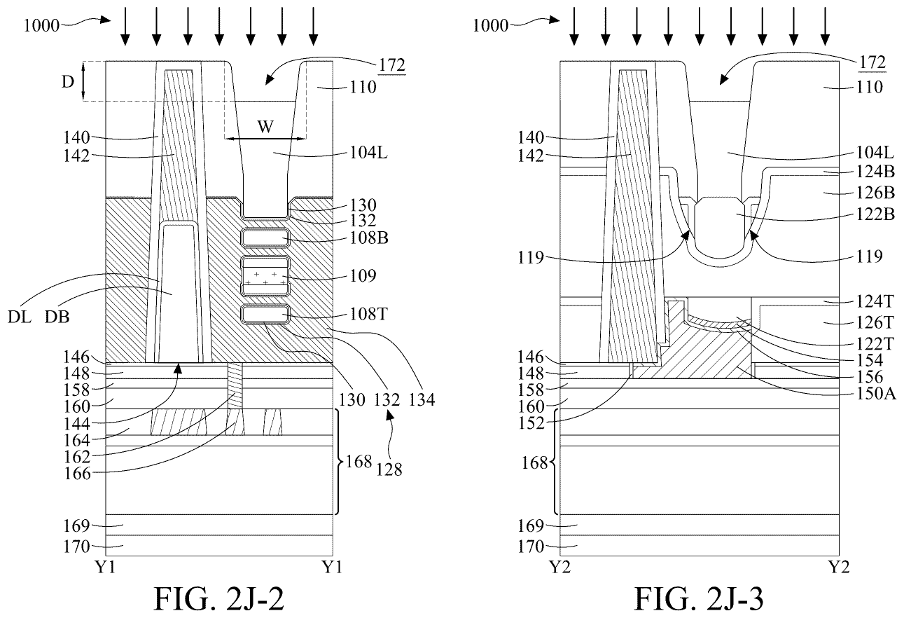

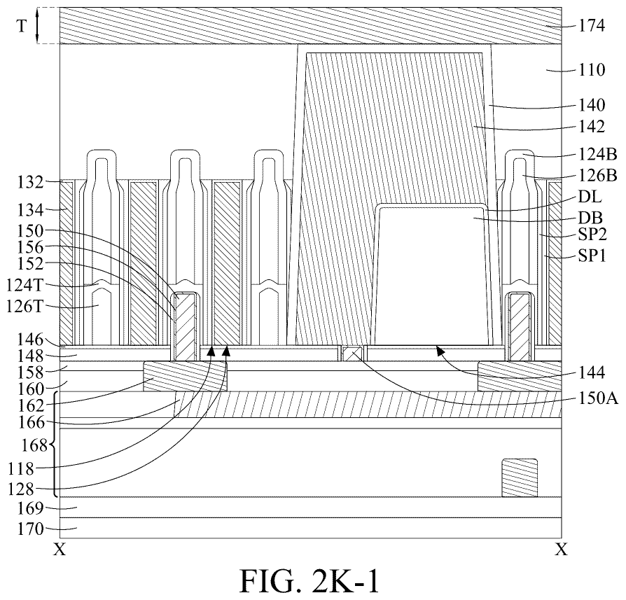

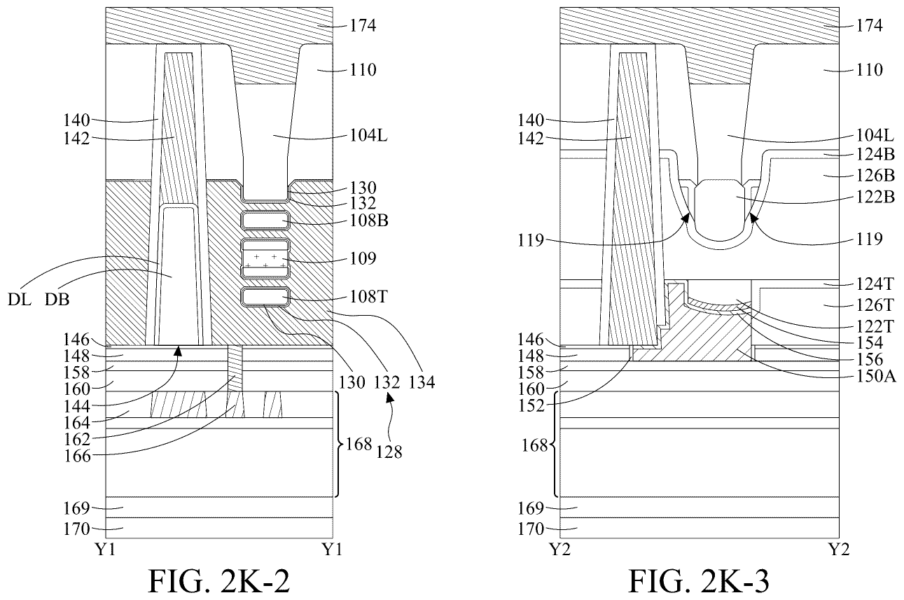

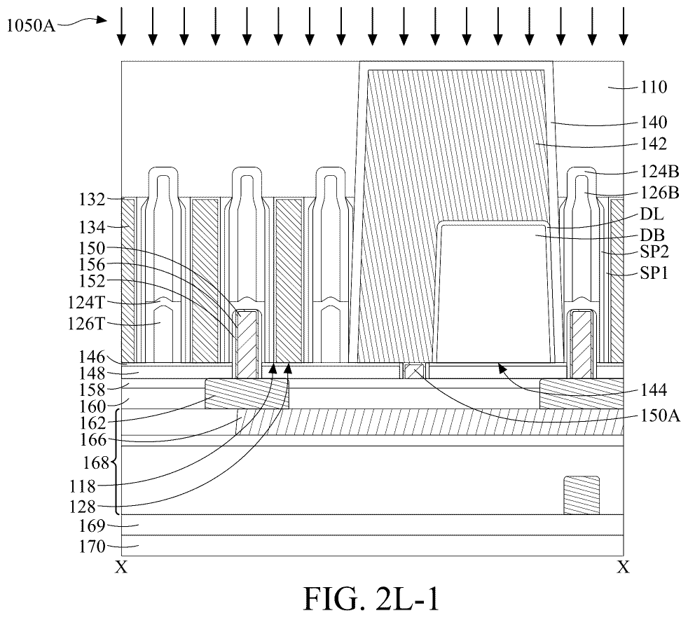

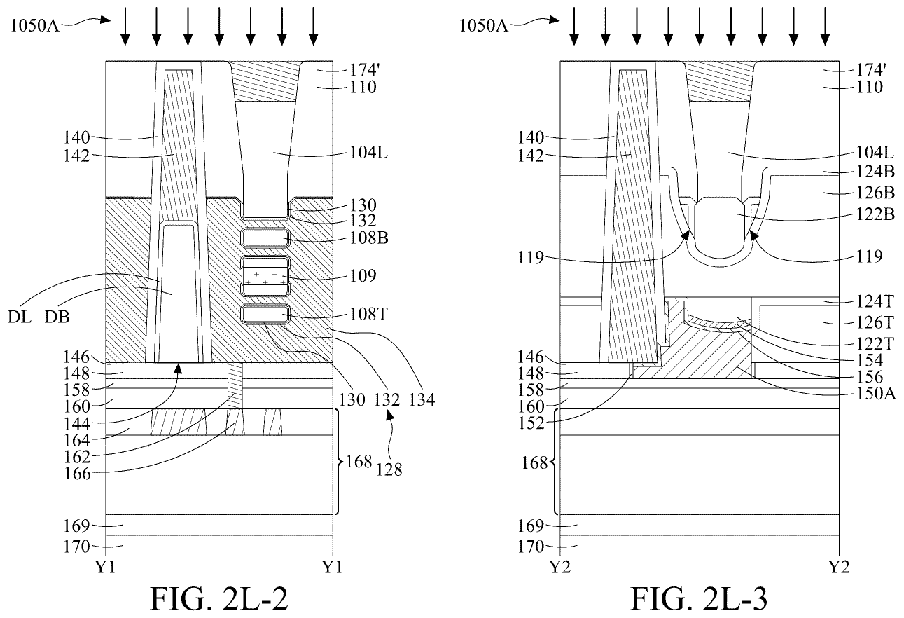

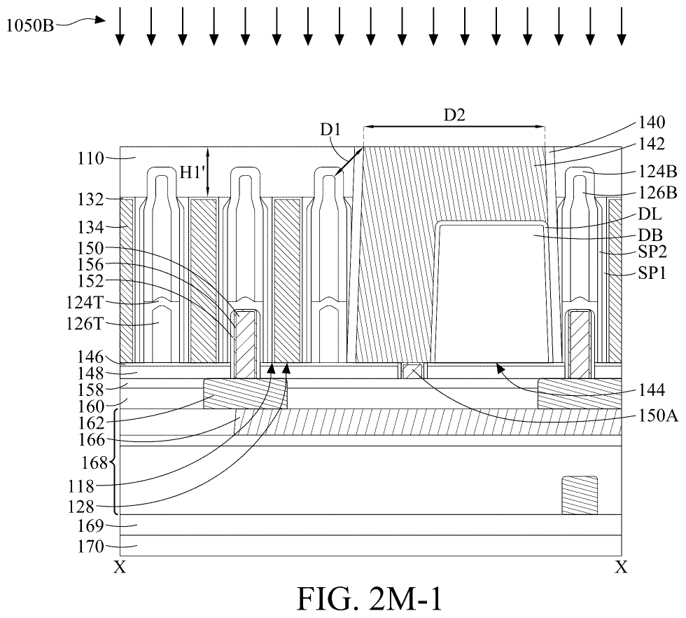

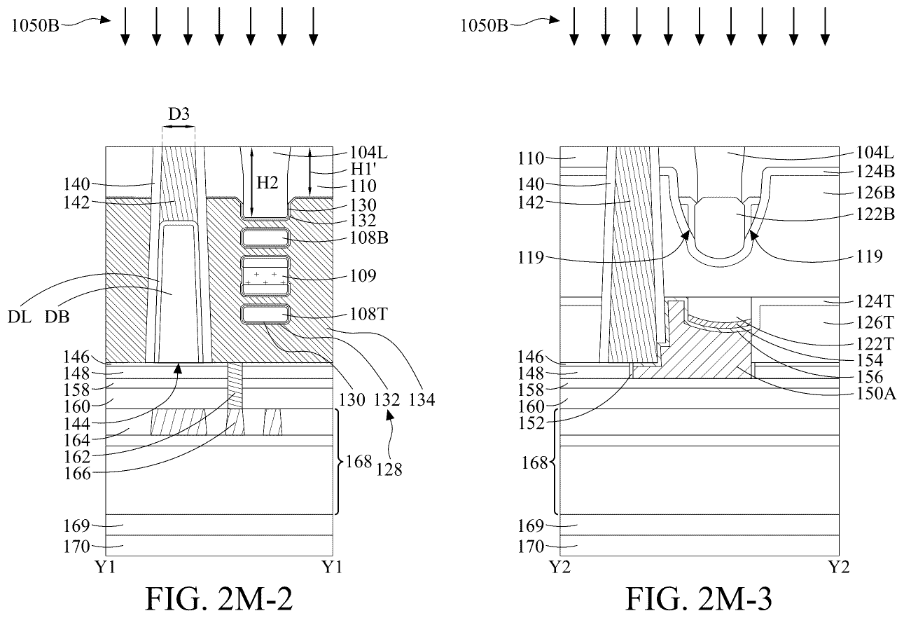

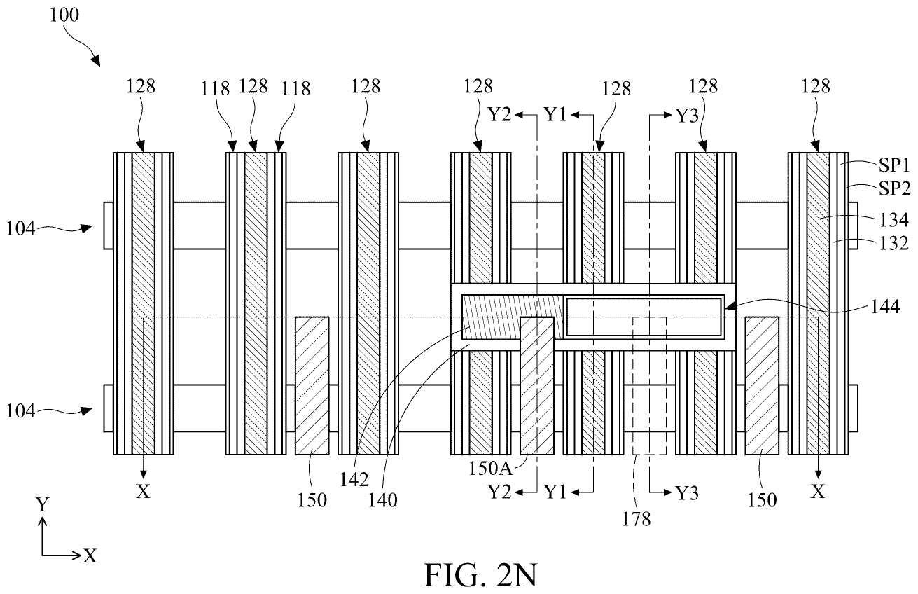

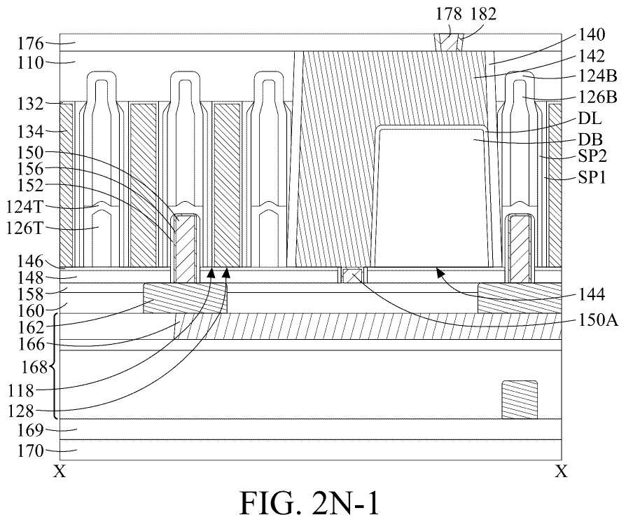

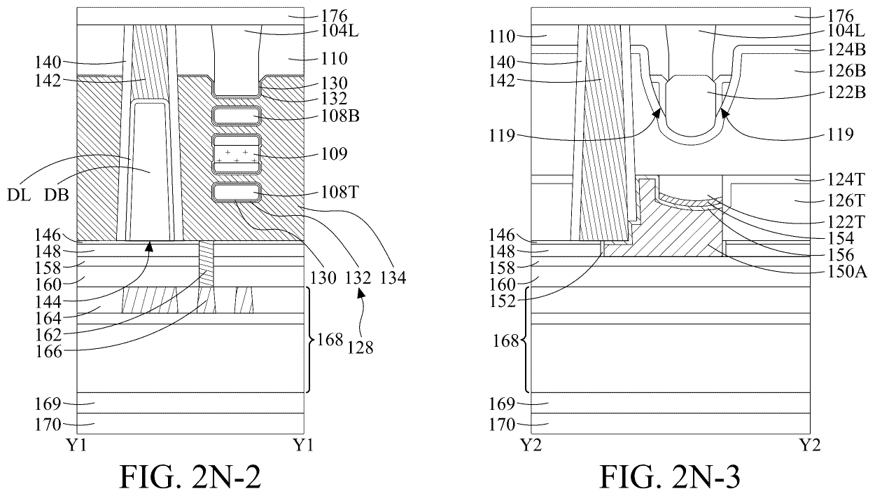

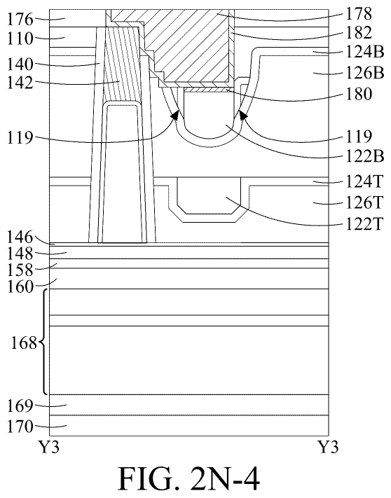

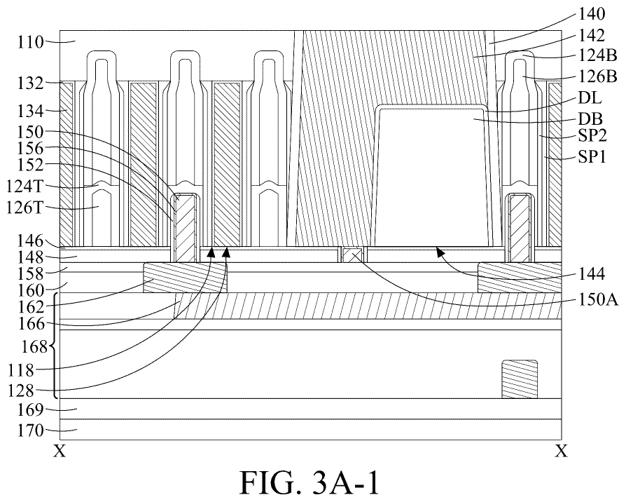

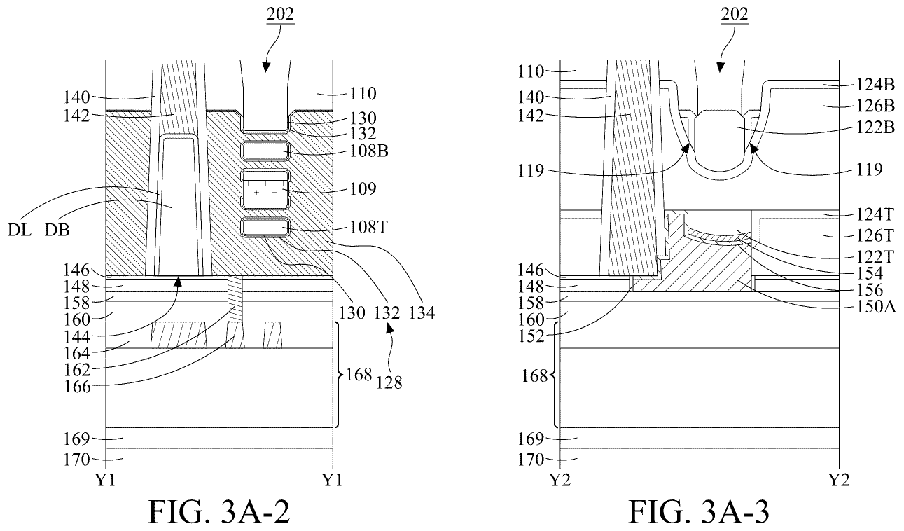

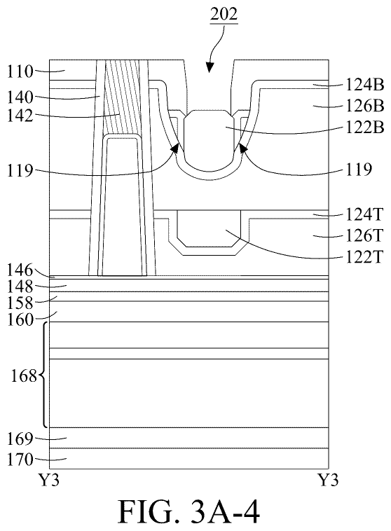

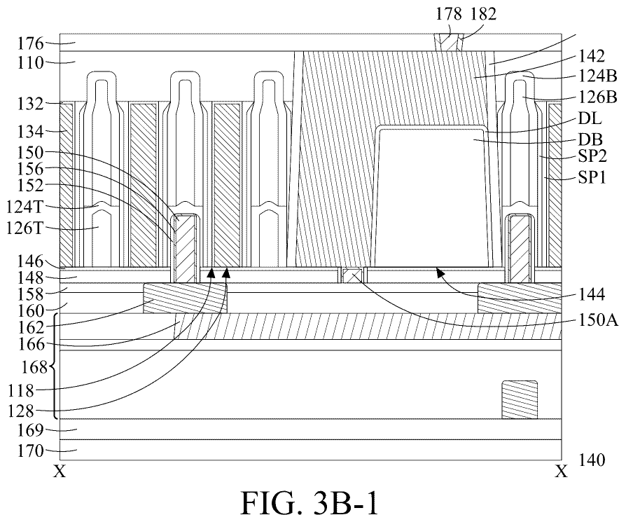

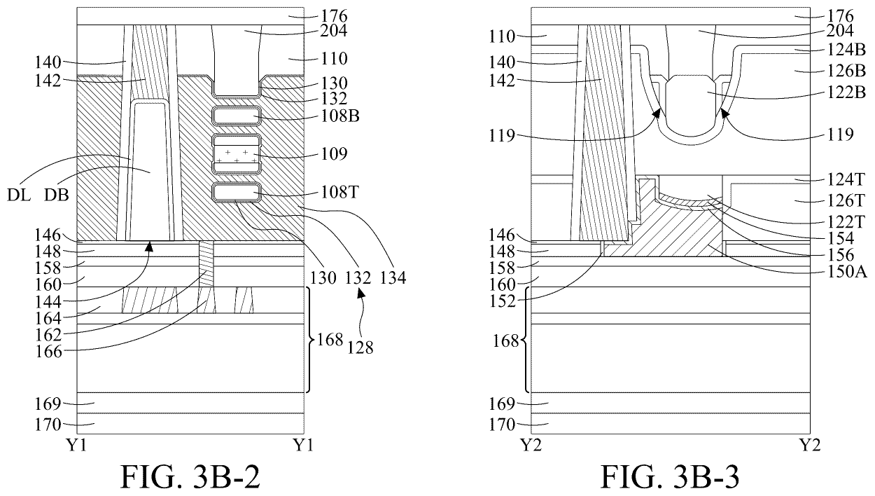

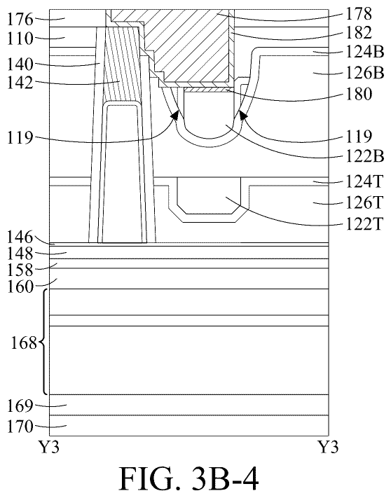

FIGS. 2A through 2N-4 are schematic views illustrating the formation of a semiconductor structure 100 at various intermediate stages, in accordance with some embodiments of the disclosure. FIGS. 2A, 2D, 2E, 2F, 2G, 2H, 2N are top views of the semiconductor structure 100. The figures ending with “−1” (e.g., FIGS. 2A-1, 2N-1, etc.) are cross-sectional views corresponding to line X-X of the top views; the figures ending with “−2” (e.g., FIGS. 2A-2, 2N-2, etc.) are cross-sectional views corresponding to line Y1-Y1 of the top views; figures ending with “−3” (e.g., FIGS. 2A-3, 2N-3, etc.) are cross-sectional views correspond to line Y2-Y2 of the top views. FIG. 2N-4 is a cross-sectional view corresponding to line Y3-Y3 of FIG. 2N.

FIGS. 2A to 2A-3 illustrate a semiconductor structure 100 after the formation of active regions 104, an isolation structure 110, dummy gate structures 112, gate spacer layers 118 and fin spacer layers 119, in accordance with some embodiments.

The semiconductor structure 100 includes a substrate 102 and active regions 104 formed over the substrate 102, as shown in FIGS. 2A to 2A-3, in accordance with some embodiments. The semiconductor structure 100 is used to form a CFET device in which n-type devices and p-type devices are stacked on top of each other. The frontside of the semiconductor structure 100 (or the substrate 102) faces upward, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active regions 104 extend in the X direction. That is, the active regions 104 have longitudinal axes parallel to the X direction, in accordance with some embodiments. The formation of the active region 104 includes forming a stack over the substrate 102, in accordance with some embodiments. The stack is a multi-layered structure which includes first semiconductor layers 106B and 106T, second semiconductor layers 108B and 108T, and a middle layer 105, in accordance with some embodiments.

In some embodiments, the first semiconductor layers 106B and 106T are made of a first semiconductor material, and the second semiconductor layers 108B and 108T are made of a second semiconductor material with a different composition than the first semiconductor material. The first semiconductor material for the first semiconductor layers 106B and 106T has a different lattice constant than the second semiconductor material for the second semiconductor layers 108B and 108T, in accordance with some embodiments. In some embodiments, the first semiconductor material and the second semiconductor material have different oxidation rates and/or etching selectivity.

In some embodiments, the first semiconductor layers 106B and 106T are made of SiGe, where the percentage of germanium (Ge) in the SiGe is in a range from about 20 atomic % to about 50 atomic %, and the second semiconductor layers 108B and 108T are made of pure or substantially pure silicon. In some embodiments, the first semiconductor layers 106B and 106T are Si₁₋ₓGeₓ, where x is more than about 0.3, or Ge (x=1.0) and the second semiconductor layers 108B and 108T are Si or Si_{1-y}Ge_{y}, where y is less than about 0.4, and x>y.

In some embodiments, the second semiconductor layer 108B and the second semiconductor layer 108T are made of the same material, such as Si. In some embodiments, the second semiconductor layer 108B and the second semiconductor layer 108T are made of different materials depending on the overall performance of the resulting CFET devices, for example, the second semiconductor layers 108B are made of SiGe, and the second semiconductor layers 108T are made of Si. The layers 106B, 106T, 108B and 108T and 105 of the stack are depositing using an epitaxial growth process, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the middle layer 105 is made of the same material as the first semiconductor layers 106B and 106T, e.g., SiGe. In some embodiments, the middle layer 105 is a SiGe layer with a higher germanium concentration than the first semiconductor layers 106B and 106T so that the middle layer 105 may be selectively etched relative the first semiconductor layers 106B and 106T.

The stack is defined as a bottom device region and a top device region above the bottom device region, where the middle layer 105 is interposed between the bottom device region and the top device region, in accordance with some embodiments. The bottom device region includes the semiconductor layers 106B and 108B while the top device region includes the semiconductor layers 106T and 108T, in accordance with some embodiments. In some embodiments, the bottom device region is used to form p-type devices (e.g., p-channel nanostructure transistors), and the top device region is used to form n-type devices (e.g., n-channel nanostructure transistors). In some other embodiments, the bottom device region is used to form n-type devices (e.g., n-channel nanostructure transistors), and the top device region is used to form p-type devices (e.g., p-channel nanostructure transistors).

Although FIGS. 2A-1 to 2A-4 illustrate two second semiconductor layers 108T and two second semiconductor layers 108B, the number of the second semiconductor layers 108T and the number of the second semiconductor layers 108B are not limited thereto. For example, the number of the second semiconductor layers 108T and the number of the second semiconductor layers 108B may be 1 or 3, and is less than 10. The first semiconductor layers 106B are stacked in an alternating manner with the second semiconductor layers 108B, and the first semiconductor layers 106T (when there is more than one) are stacked in an alternating manner with the second semiconductor layers 108T. In addition, the number of the second semiconductor layers 108T may be different from the number of the second semiconductor layers 108B. In some embodiments, the thickness of each of first semiconductor layers 106B and 106T is in a range from about 6 nm to about 16 nm. In some embodiments, the thickness of each of the second semiconductor layers 108B and 108T is in a range from about 4 nm to about 8 nm.

The first semiconductor layers 106B and 106T are configured as sacrificial layers and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments.

The formation of the active regions 104 further includes patterning the stack and underlying substrate 102 using photolithography and etching processes, thereby forming trenches and the active regions 104 protruding from between trenches, in accordance with some embodiments. The portion of the substrate 102 protruding from between the trenches serves as lower fin elements 104L of the active regions 104, in accordance with some embodiments. The remainder of the stack serves as the upper fin elements of the active regions 104, in accordance with some embodiments. In some embodiments, the active regions 104 may be referred to as a fin or a fin structure. Although two active regions 104 are shown, the number of the active regions 104 is not limited thereto, and may depend on the performance and design demands of the resulting semiconductor device.

An isolation structure 110 is formed to surround the lower fin elements 104L of the active regions 104, as shown in FIGS. 2A-1 to 2A-3, in accordance with some embodiments. The isolation structure 110 is configured to electrically isolate neighboring active regions 104 and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) to expose the sidewalls of the upper fin elements of the active regions 104, in accordance with some embodiments. The remaining insulating material serves as the isolation structure 110, in accordance with some embodiments.

Dummy gate structures 112 are formed across the active regions 104 and the isolation structure 110, as shown in FIGS. 2A, 2A-1 and 2A-2, in accordance with some embodiments. The dummy gate structures 112 are configured as sacrificial structures and will be replaced with the final gate stacks, in accordance with some embodiments. In some embodiments, the dummy gate structures 112 extend in the Y direction. That is, the dummy gate structures 112 have longitudinal axes parallel to the Y direction, in accordance with some embodiments. The dummy gate structures 112 surround the channel regions of the active regions 104, in accordance with some embodiments. Each of the dummy gate structures 112 includes a dummy gate dielectric layer 114 and a dummy gate electrode layer 116 formed over the dummy gate dielectric layer 114, as shown in FIGS. 2A-1 and 2A-2, in accordance with some embodiments.

In some embodiments, the dummy gate dielectric layer 114 is conformally formed along the upper fin element of the active region 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof. In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112.

The patterning process includes forming a patterned hard mask layer (not shown) over the material for the dummy gate electrode layer 116, in accordance with some embodiments. The patterned hard mask layer corresponds to and overlaps the channel regions of the active regions 104, in accordance with some embodiments. The materials for the dummy gate dielectric layer 114 and the dummy gate electrode layer 116, uncovered by the patterned hard mask layer, are etched away until the active regions 104 and the top surface of the isolation structure 110 are exposed, in accordance with some embodiments.

Gate spacer layers 118 are formed along opposite sidewalls of the dummy gate structures 112, and fin spacer layers 119 are formed along opposite sidewalls of the active regions 104, as shown in FIGS. 2A-1 and 2A-3, in accordance with some embodiments. The gate spacer layers 118 extend in the Y direction and across the active regions 104 and the isolation structure 110, in accordance with some embodiments. The fin spacer layers 119 extend in the X direction, in accordance with some embodiments. The gate spacer layers 118 are used to offset the subsequently formed source/drain features and separate the source/drain features from the gate structures 112, in accordance with some embodiments. The fin spacer layers 119 are used to confine the growth of epitaxial material to prevent neighboring source/drain features from merging with each other, in accordance with some embodiments.

In some embodiments, the gate spacer layers 118 and the fin spacer layers 119 are formed from one or more continuous dielectric material(s). For example, in some embodiments, the formation of the gate spacer layers 118 and the fin spacer layers 119 includes globally and conformally depositing spacer layers SP1 and SP2 over the semiconductor structure 100 using ALD, CVD (such as LPCVD, PECVD or HDP-CVD or a combination thereof, followed by an anisotropic etching process, in accordance with some embodiments.

In some embodiments, the spacer layers SP1 and SP2 are made of dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the spacer layer SP1 and the spacer layer SP2 are made of different materials and have different dielectric constant values. For example, the spacer layers SP1 and SP2 are made of SiOCN with different compositions (e.g., different carbon concentrations) and different dielectric constants. In some other embodiments, the spacer layers SP1 and SP2 are the same material.

After the anisotropic etching process, the vertical portions of the spacer layers SP1 and SP2 left remaining on the opposite sides of the dummy gate structures 112 form the gate spacer layers 118, in accordance with some embodiments. The vertical portions of the spacer layers SP1 and SP2 left remaining on the opposite sides of the active regions 104 form the fin spacer layers 119, in accordance with some embodiments.

FIGS. 2B to 2B-3 illustrate the semiconductor structure 100 after the formation of source/drain recesses 120 and an insulating layer 109, in accordance with some embodiments.

An etching process is performed to recess the source/drain regions of the active regions 104, thereby forming source/drain recesses 120, as shown in FIG. 2B-3, in accordance with some embodiments. The etching process may be an anisotropic etching process such as dry plasma etching, an isotropic etching process such as dry chemical etching, remote plasma etching or wet chemical etching, or a combination thereof. The gate spacer layers 118 and the dummy gate structures 112 may serve as etch masks such that the source/drain recesses 120 are formed self-aligned on opposite sides of the dummy gate structures 112, in accordance with some embodiments. The source/drain recesses 120 may extend a distance into the lower fin elements 104L, in accordance with some embodiments.

In the etching process, the isolation structure 110 is also recessed, thereby forming STI recesses, as shown in FIGS. 2B-1 and 2B-2, in accordance with some embodiments. In some embodiments, the bottom of the STI recess extends downward to a deeper position than the bottom of the source/drain recess 120. In some other embodiments, the isolation structure 110 may be unrecessed, or slightly recessed. In addition, the fin spacer layers 119 are also recessed in the etching process.

An etching process is performed to remove the middle layer 105, thereby forming a gap, and then an insulating layer 109 is formed in the gap, as shown in FIG. 2B-2, in accordance with some embodiments. In some embodiments, the insulating layer 109 is connected to the topmost second semiconductor layer 108B and the bottommost second semiconductor layer 108T. The insulating layer 109 may be used to physically and electrically isolate the top second semiconductor layers 108T (collectively) from the bottom second semiconductor layers 108B (collectively). In some embodiments, the insulating layer 109 is made of dielectric material such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), or a combination thereof.

In some embodiments, the insulating layer 109 is formed by depositing a dielectric material to fill the gap, and then etching away the dielectric material outside the gap. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

An etching process is performed to laterally recess, from the source/drain recesses 120 in the X direction, the first semiconductor layers 106B and 106T of the active region 104, thereby forming notches (not shown) under the gate spacer layer 118. Inner spacer layers (not shown) are then formed in the notches to about the recessed side surfaces of the first semiconductor layers 106B and 106T, in accordance with some embodiments. Although not shown in the figures, the inner spacer layers may be present in the front and back of FIG. 2B-2 and in the cross-section through the gate spacer layer. In some embodiments, the inner spacer layers are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), or a combination thereof. In some other embodiments, the inner spacer layer may be formed simultaneously with the insulating layer 109. For example, an etching process is performed to completely remove the middle layer 105 and laterally recess the first semiconductor layers 106B and 106T thereby forming a gap for the insulating layer 109 and notches for the inner spacer layers, and a dielectric material is deposited to fill the gap and notches, and an etching back process is performed to remove the dielectric material outside the gap and notches.

FIGS. 2C to 2C-3 illustrate the semiconductor structure 100 after the formation of bottom source/drain features 122B, top source/drain features 122T, contact etching stop layers 124B and 124T, and first interlayer dielectric layers 126B and 126T, in accordance with some embodiments.

Bottom source/drain features 122B are grown from the exposed side surfaces of the second semiconductor layers 108B and the exposed top surfaces of the lower fin elements 104L in the source/drain recesses 120 using an epitaxial growth process, as shown in FIG. 2C-3, in accordance with some embodiments. The epitaxial growth process may be MBE, MOCVD, or VPE, or another suitable technique. In some embodiments, a spacer layer may be formed to cover the exposed side surfaces of the second semiconductor layers 108T to prevent epitaxial material from being formed on second semiconductor layers 108T. After the bottom source/drain features 122B are formed, the spacer layer may be removed.

In some embodiments, the bottom source/drain features 122B are made of any suitable semiconductor material for n-type semiconductor devices or p-type semiconductor devices. In some embodiments, the bottom source/drain features 122B are doped. The concentration of the dopant in the bottom source/drain features 122B in a range from about 1×10¹⁹ cm⁻³ to about 6×10²¹ cm⁻³.

In some embodiments where the bottom device region of the active region 104 is to be formed as p-type devices (e.g., p-channel nanostructure transistors), the bottom source/drain features 122B are made of semiconductor material such as SiGe, Si, GaAs, another suitable semiconductor material, or a combination thereof. In some embodiments, the bottom source/drain features 122B are doped with the p-type dopant during the epitaxial growth process. For example, the p-type dopant may be boron (B) or BF₂. For example, the bottom source/drain features 122B may be the epitaxially grown SiGe doped with boron (B) to form silicon germanium:boron (SiGe:B) source/drain feature.

A contact etching stop layer 124B is formed over the semiconductor structure 100 to cover the bottom source/drain features 122B, as shown in FIGS. 2C-1 and 2C-3, in accordance with some embodiments. In some embodiments, the contact etching stop layer 124B is made of dielectric material, such as silicon nitride (SiN), silicon oxide (SiO₂), silicon oxynitride (SiON), silicon carbide (SiC), oxygen-doped silicon carbide (SiC:O), oxygen-doped silicon carbonitride (Si(O)CN), or a combination thereof. In some embodiments, dielectric material for the contact etching stop layer 124B is globally and conformally deposited over the semiconductor structure 100 using CVD (such as LPCVD, PECVD, HDP-CVD, or HARP), ALD, another suitable method, or a combination thereof.

Afterward, a first interlayer dielectric layer 126B is formed over the contact etching stop layer 124B, as shown in FIGS. 2C-1 and 2C-3, in accordance with some embodiments. The first interlayer dielectric layer 126B overfills the space between dummy gate structures 112, in accordance with some embodiments. In some embodiments, the first interlayer dielectric layer 126B is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the first interlayer dielectric layer 126B and the contact etching stop layer 124B are made of different materials and have a great difference in etching selectivity. In some embodiments, the dielectric material for the first interlayer dielectric layer 126B is deposited using such as CVD (such as HDP-CVD, PECVD, HARP or FCVD), another suitable technique, or a combination thereof. The dielectric materials for the contact etching stop layer 124B and the first interlayer dielectric layer 126B above the top surface of the dummy gate electrode layer 116 are removed using such as CMP, and then are etched-back until the side surfaces of the second semiconductor layers 108T (collectively) are exposed, in accordance with some embodiments. In some embodiments, the side surfaces of the bottommost second semiconductor layer 108T remain covered by the first interlayer dielectric layer 126B and the contact etching stop layer 124B.

Top source/drain features 122T are grown from the exposed side surfaces of the topmost second semiconductor layer 108T in the source/drain recesses 120 using an epitaxial growth process, as shown in FIG. 2C-3, in accordance with some embodiments. The epitaxial growth process may be MBE, MOCVD, or VPE, or another suitable technique.

In some embodiments, the top source/drain features 122T are made of any suitable semiconductor material for n-type semiconductor devices or p-type semiconductor devices. In some embodiments, the top source/drain features 122T are doped. The concentration of the dopant in the top source/drain features 122T in a range from about 1×10¹⁹ cm⁻³ to about 6×10²¹ cm⁻³.

In some embodiments where the top device region of the active region 104 is to be formed as n-type devices (e.g., n-channel nanostructure transistors), the top source/drain features 122T are made of semiconductor material such as SiP, SiAs, SiCP, SiC, Si, GaAs, another suitable semiconductor material, or a combination thereof. In some embodiments, the top source/drain features 122T are doped with the n-type dopant during the epitaxial growth process. For example, the n-type dopant may be phosphorous (P) or arsenic (As). For example, the top source/drain features 122T may be the epitaxially grown Si doped with phosphorous to form silicon:phosphor (Si:P) source/drain features and/or arsenic to form silicon:arsenic (Si:As) source/drain feature.

In some other embodiments where the bottom device region is used to form n-type devices and the top device region is used to form p-type devices, the bottom source/drain features 122B are doped with n-type dopants while the top source/drain features 122T are doped with p-type dopants.

A contact etching stop layer 124T is formed over the semiconductor structure 100 to cover the top source/drain features 122T, and a first interlayer dielectric layer 126T is formed over the contact etching stop layer 124T, in accordance with some embodiments. In some embodiments, the material of the contact etching stop layer 124T and the first interlayer dielectric layer 126T may be the same as or similar to the material of the contact etching stop layer 124B and the first interlayer dielectric layer 126B, respectively.

The dielectric materials for the contact etching stop layer 124T and the first interlayer dielectric layer 126T above the top surface of the dummy gate electrode layer 116 are removed using such as CMP to expose the top surfaces of the dummy gate structures 112, in accordance with some embodiments.

FIGS. 2D to 2D-3 illustrate the semiconductor structure 100 after the formation of final gate stacks 128, in accordance with some embodiments.

The dummy gate structures 112 are removed using an etching process to form gate trenches between the gate spacer layers 118, and then the first semiconductor layers 106B and 106T are removed using an etching process to form gaps, in accordance with some embodiments. In some embodiments, the gate trenches expose the channel regions of the active regions. In some embodiments, the etching processes includes plasma dry etching, a dry chemical etching, and/or a wet etching.

After the etching processes, the main surfaces of the second semiconductor layers 108B and 108T are exposed, in accordance with some embodiments. The exposed second semiconductor layers 108B and 108T form nanostructures 108B and 108T, in accordance with some embodiments. The nanostructures 108B and 108T are vertically stacked and spaced apart from one other, in accordance with some embodiments. The nanostructure 108B functions as the channel of the bottom device of the CFET, and the nanostructure 108T functions as the channel of the top device of the CFET, in accordance with some embodiments. Although two nanostructures 108B and two nanostructures are shown in FIGS. 2D-2, the number is not limited to one, and can be two (as shown in FIG. 1) or three, and is less than 10.

Final gate stacks 128 are formed in the gate trenches and gaps as shown in FIGS. 2D, 2D-1 and 2D-2, in accordance with some embodiments. The nanostructures 108B and 108T are wrapped by the final gate stacks 128, in accordance with some embodiments. In some embodiments, the final gate stacks 128 extend in the Y direction. The final gate stacks 128 have longitudinal axes parallel to the Y direction, in accordance with some embodiments. In some embodiments, each of the final gate stacks 128 includes an interfacial layer 130, a gate dielectric layer 132 and a metal gate electrode layer 134, as shown in FIGS. 2D-1 and 2D-2, in accordance with some embodiments.

The interfacial layer 130 is formed on the exposed surfaces of the nanostructures 108B and 108T, in accordance with some embodiments. The interfacial layer 130 wraps around the nanostructures 108B and 108T, in accordance with some embodiments. In some embodiments, the interfacial layer 130 is made of a chemically formed silicon oxide. In some embodiments, the interfacial layer 130 is nitrogen-doped silicon oxide. In some embodiments, the interfacial layer 130 is formed using one or more cleaning processes such as including ozone (03), ammonia hydroxide-hydrogen peroxide-water mixture, and/or hydrochloric acid-hydrogen peroxide-water mixture. Semiconductor material from the nanostructures 108B and 108T and the lower fin element 104L is oxidized to form the interfacial layer 130, in accordance with some embodiments.

The gate dielectric layer 132 is formed conformally along the interfacial layer 130 to be wrapped around the nanostructures 108B and 108T, in accordance with some embodiments. The gate dielectric layer 132 is also conformally formed along the upper surface of the isolation structure 110, in accordance with some embodiments. The gate dielectric layer 132 may be high-k dielectric layer. In some embodiments, the high-k dielectric layer is dielectric material with high dielectric constant (k value), for example, greater than 9, such as greater than 13. In some embodiments, the high-k dielectric layer includes hafnium oxide (HfO₂), TiO₂, HfZrO, Ta₂₀₃, HfSiO₄, ZrO₂, ZrSiO₂, LaO, Al₂O₃, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃(BST), Si₃N₄, silicon oxynitride (SiON), a combination thereof, or another suitable material. The high-k dielectric layer may be deposited using ALD, PVD, CVD, and/or another suitable technique.

The metal gate electrode layer 134 is formed to overfill remainders of the gate trenches and gaps, in accordance with some embodiments. In some embodiments, the metal gate electrode layer 134 is made of more than one conductive material, such as a metal, metal alloy, conductive metal oxide and/or metal nitride, another suitable conductive material, or a combination thereof. For example, the metal gate electrode layer 134 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof. The metal gate electrode layer 134 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to the next layer, and a metal fill layer to reduce the total resistance of gate stacks, and/or another suitable layer. The metal gate electrode layer 134 may be formed using ALD, PVD, CVD, e-beam evaporation, or another suitable technique.

In some embodiments, the metal gate electrode layer 134 may be or includes a single work function metal that continuously surrounds the nanostructures 108B and 108T. In some other embodiments where the bottom device region is used to form p-type devices and the top device region is used to form n-type devices, the metal gate electrode layer 134 includes a p-type work function metal surrounding the nanostructure 108B, and an n-type work function metal surrounding the nanostructure 108T. In such embodiments, an etch back process may be performed to etch the p-type work function metal below nanostructures 108T prior to depositing the n-type work function metal. A planarization process such as CMP may be performed on the semiconductor structure 100 to remove the materials of the gate dielectric layer 132 and the metal gate electrode layer 134 formed above the top surface of the first interlayer dielectric layer 126T, in accordance with some embodiments.

The bottom portion of the final gate stacks 128 that are wrapped around the bottom nanostructures 108B combine with the neighboring bottom source/drain features 122B to form a bottom transistor BT (FIG. 1), e.g., a p-channel nanostructure transistor. The top portion of the final gate stacks 128 that is wrapped around the top nanostructure 108T combines with the neighboring top source/drain features 122T to form a top transistor TT (FIG. 1), e.g., an n-channel nanostructure transistor.

The n-channel top transistor TT is directly stacked above the p-channel bottom transistors BT thereby constructing a CFET, in accordance with some embodiments. The final gate stacks 128 engage the channel region of the CFET so that current can flow between the source/drain features 122B/122T during operation. In some other embodiments, the top transistors TT are p-channel nanostructure transistors, and the bottom transistors BT are n-channel nanostructure transistors.

FIGS. 2E to 2E-3 illustrate the semiconductor structure 100 after the formation of a gate-cut opening 138, in accordance with some embodiments.

A patterned mask layer 136 is formed over the final gate structures 128 and the first interlayer dielectric layer 126T, as shown in FIGS. 2E to 2E-3, in accordance with some embodiments. The patterned mask layer 136 has an opening pattern 137, in accordance with some embodiments. The opening 137 of the patterned mask layer 136 is aligned over or corresponds to the isolation structure 110 between the active regions 104, in accordance with some embodiments. Although the opening 137 extends across three final gate structures 128, the embodiments are not limited thereto, for example, the opening 137 extends across extends fourth final gate structures 128.

The patterned mask layer 136 may be a tri-layer mask structure which includes a bottom hard mask layer, a middle hard mask layer and a top photoresist mask, in accordance with some embodiments. For example, the bottom hard mask layer may be bottom anti-reflective coating (BARC) layer such as an inorganic material or an organic material (e.g., polymer, oligomer, or monomer). In some embodiments, the bottom hard mask layer is made of organic material including carbon and oxygen, which is made of cross-linked photo-sensitive material. In some embodiments, the middle hard mask layer is made of silicon oxide-based material (e.g., silicon nitride (SiN), silicon oxynitride (SiON), silicon oxide (SiO), a nitrogen-free anti-reflection layer (NFARL), or carbon-doped silicon dioxide (e.g., SiO₂:C)), metal oxide (e.g., zinc oxide (ZnO), aluminum oxide (Al₂O₃), tin oxide (SnO), lead oxide (PbO), beryllium oxide (BeO), titanium oxide (TiO), or chromium oxide (CrO, Cr₂O₃, Cr₂O₃ or Cr₃O₄), titanium nitride (TiN), boron nitride (BN), another suitable material, or a combination thereof.

The top photoresist mask is formed by a photolithography process, in accordance with some embodiments. The photolithography process can include forming a photoresist layer, for example, by spin coating, performing a pre-exposure baking process, performing an exposure process using a mask (or a reticle), performing a post-exposure baking process, and performing a developing process. During the exposure process, the photoresist layer is exposed to radiation energy, where the mask blocks, transmits, and/or reflects radiation to the photoresist layer depending on the mask pattern of the mask and/or mask type, such that an image is projected onto the photoresist layer that corresponds with the mask pattern. Since the photoresist layer is sensitive to radiation energy, exposed portions of the resist layer chemically change, and exposed (or non-exposed) portions of the resist layer are dissolved during the developing process depending on the characteristics of the resist layer and the characteristics of the developing solution used in the developing process.

An etching process is performed on the semiconductor structure 100 using the patterned mask layer 136, in accordance with some embodiments. The etching process may be anisotropic etching process such as dry plasma etching. The etching process removes the bottom hard mask layer and the middle hard mask layer to form the opening pattern 137, in accordance with some embodiments. The etching process may be an anisotropic etching process such as dry plasma etching, an isotropic etching process such as dry chemical etching, remote plasma etching or wet chemical etching, or a combination thereof. Although not shown, a gate-cut opening (not shown) extending across only one final gate stack 128 may be formed.

The etching process further removes the final gate stacks 128, the gate spacer layers 118, the first interlayer dielectric layers 126B and 126T, and the contact etching stop layers 124B and 124T exposed from the opening pattern 137, thereby forming a gate-cut opening 138, in accordance with some embodiments. In some embodiments, the gate-cut opening 138 further extends through the isolation structure 110 and extends to the substrate 102, as shown in FIGS. 2E to 2E-3. In some embodiments, the patterned mask layer 136 is removed in the etching process, or by another process.

FIGS. 2F to 2F-3 illustrate the semiconductor structure 100 after the formation of a dielectric layer 140 and a conductive feature 142, in accordance with some embodiments.

A dielectric layer 140 is formed along the sidewalls and the bottom surface of the gate-cut opening 138, FIGS. 2F to 2F-3, in accordance with some embodiments. The formation of the dielectric layer 140 includes conformally depositing dielectric material along the semiconductor structure 100 to partially fill the gate-cut opening 138. In some embodiments, the gate-cut opening (not shown) extending across one final gate stack is overfilled by the dielectric material, thereby forming a gate-cut feature, which may also be referred to as cut metal gate (CMG) patterns.

The dielectric material may be silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. The formation of the dielectric layer 140 further includes etching back the dielectric material to remove the portion of the dielectric material along the top surfaces of the final gate stacks 128 and the first interlayer dielectric layer 126T. In some embodiments, the portion of the dielectric material partially filled in the gate-cut opening 138 is thinned down, thereby enlarging the remaining space of the gate-cut opening 138.

A conductive feature 142 is formed on the dielectric layer 140 in the gate-cut opening 138, as shown in FIGS. 2F to 2F-3, in accordance with some embodiments. The conductive feature 142 is nested within and/or surrounded by the dielectric layer 140, in accordance with some embodiments. In some embodiments, the conductive feature 142 may also be referred to as the VLI (vertical local interconnect) feature, which transmits the signal from the frontside to the backside or from the backside to the frontside. In some embodiments, the conductive feature 142 is electrically connected to the drain terminal of the top device and to the drain terminal of the bottom device, which is adjacent to the top device. The conductive feature 142 is electrically isolated from the final gate stacks 128 by the dielectric layer 140, in accordance with some embodiments. The conductive feature 142 is physically isolated from the final gate stacks 128 by the dielectric layer 140, in accordance with some embodiments.

The formation of the conductive feature 142 includes depositing metal material along the semiconductor structure 100 to overfill the remaining space of the gate-cut opening 138 using CVD, PVD, e-beam evaporation, ALD, electroplating (ECP), electroless deposition (ELD), another suitable method, or a combination thereof. The metal material may be tungsten (W), titanium (Ti), cobalt (Co), nickel (Ni), tantalum (Ta), copper (Cu), rhodium (Rh), iridium (Ir), platinum (Pt), aluminum (Al), ruthenium (Ru), molybdenum (Mo), tantalum nitride (TaN), titanium (Ti), titanium nitride (TiN), cobalt tungsten (CoW), another suitable metal material, or a combination thereof. The formation of the conductive feature 142 further includes planarizing the metal material to remove the metal material from the top surfaces of the final gate stacks 128 and the first interlayer dielectric layer 126T using CMP or an etching-back process.

FIGS. 2G to 2G-3 illustrate the semiconductor structure 100 after the formation of an insulating feature 144, in accordance with some embodiments.

An insulating feature 144 is formed in the conductive feature 142, as shown in FIGS. 2G, 2G-1 and 2G-2, in accordance with some embodiments. The insulating feature 144 extends across or corresponds to two final gate stacks 128, as shown in FIG. 2G, in accordance with some embodiments. The insulating feature 144 partially penetrates through the conductive feature 142, as shown in FIGS. 2G-1 and 2G-2, in accordance with some embodiments. The bottom surface of the insulating feature 144 is located at a higher level than the bottom surface of the final gate stacks 128, in accordance with some embodiments. In some embodiments, the insulating feature 144 is configured to reduce the overlapping area between the conductive feature 142 and the final gate stacks 128, thereby reducing the overall cell capacitance of the CFET device.

In some embodiments, the insulating feature 144 includes a dielectric liner DL and a dielectric bulk layer (DB) on the dielectric liner (DL). The dielectric liner DL is nested within and/or surrounded by the dielectric bulk layer DB, in accordance with some embodiments. In some embodiments, the dielectric liner DL and the dielectric bulk layer DB are made of dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the dielectric liner DL and the dielectric bulk layer DB are made of different materials and have different dielectric constant values. For example, the dielectric liner DL is made of SiN, and the dielectric bulk layer DB is made of SiO. The formation of the insulating feature 144 includes patterning the conductive feature 142 to form an opening using photolithography and etching processes, depositing dielectric materials for dielectric liner DL and the dielectric bulk layer DB, planarizing the dielectric materials from the top surface of the first interlayer dielectric layer 126T.

FIGS. 2H to 2H-3 illustrate the semiconductor structure 100 after the formation of an etching stop layer 146, a second interlayer dielectric layer 148, frontside contact structures 150, an etching stop layer 158, a third interlayer dielectric layer 160, vias 162, and an interconnection structure 168, in accordance with some embodiments.

An etching stop layer 146 is formed over the semiconductor structure 100, and a second interlayer dielectric layer 148 is formed over the etching stop layer 146, as shown in FIGS. 2H-1 to 2H-3, in accordance with some embodiments. In some embodiments, the material of the etching stop layer 146 and the second interlayer dielectric layer 148 may be the same as or similar to the material of the contact etching stop layer 124B and the first interlayer dielectric layer 126B, respectively.

Contact structures 150 (including 150A) are formed on the frontside surface of the top source/drain features 122T, as shown in FIGS. 2H, 2H-1 and 2H-3, in accordance with some embodiments. The contact structures 150 penetrate through the second interlayer dielectric layer 148, the etching stop layer 146, the first interlayer dielectric layer 126T and the contact etching stop layer 124T, and land on and are electrically connected to the top source/drain feature 122T, in accordance with some embodiments. One 150A of the contact structure 150 further lands on and is electrically connected to the conductive feature 142, in accordance with some embodiments. In some embodiments, the contact structure 150A and the top source/drain feature 122T connected thereto are used for a non-Vdd/Vss node (e.g., a drain terminal).

In some embodiments, the formation of the contact structures 150 (including 150A) includes patterning the semiconductor structure 100 to form contact openings (where the contact structures 150 and 150A are to be formed) using one or more photolithography and etching processes to expose the source/drain features 122T and the conductive features 142. Contact liners 152 are formed along the sidewalls of the contact openings using a deposition process and an etching back process, in accordance with some embodiments. In some embodiments, the contact liners 152 can be an insulating material or a dielectric material (e.g., LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si). Silicide layers 154 are formed on the exposed surfaces of the source/drain features 122T. In some embodiments, the silicide layers 154 are made of WSi, NiSi, TiSi and/or CoSi.

Afterward, one or more conductive materials for the contact structures 150 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 148 are planarized using, for example, CMP.

The contact structures 150 may have a multilayer structure. For example, a barrier/adhesive layer 156 may optionally be deposited along the sidewalls and the bottom surfaces of the contact openings. The barrier/adhesive layer 156 may be made of tantalum (Ta), tantalum nitride (TaN), titanium (Ti), titanium nitride (TiN), cobalt tungsten (CoW), another suitable material, or a combination thereof. A metal bulk layer of the contact structures 150 is then deposited on the barrier/adhesive layer 156 (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

An etching stop layer 158 is formed over the semiconductor structure 100, and a third interlayer dielectric layer 160 is formed over the etching stop layer 158, as shown in FIGS. 2H-1 to 2H-3, in accordance with some embodiments. In some embodiments, the material of the etching stop layer 158 and the third interlayer dielectric layer 160 may be the same as or similar to the material of the contact etching stop layer 124B and the first interlayer dielectric layer 126B, respectively.

Some vias 162 are formed through the third interlayer dielectric layer 160 and the etching stop layer 158 and land on the contact structures 150, and some other vias 162 are formed through the third interlayer dielectric layer 160, the etching stop layer 158, the second interlayer dielectric layer 148, the etching stop layer 146 and land on the metal gate electrode layer 134 of the final gate stack 128, as shown in FIGS. 2H-1 and 2H-2, in accordance with some embodiments. The vias 162, electrically connected to the final gate stacks 128, may also be referred to as gate vias (VG), and the vias 162, electrically connected to source/drain terminals of the nanostructure, may also be referred to as source/drain vias (VS or VD), in accordance with some embodiments.

In some embodiments, the formation of the vias 162 includes patterning the semiconductor structure 100 to form via openings using photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the third interlayer dielectric layer 160 are planarized using, for example, CMP. The vias 162 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

A frontside interconnect structure 168 is formed over the semiconductor structure 100, as shown in FIGS. 2H-1 to 2H-3, in accordance with some embodiments. In some embodiments, the frontside interconnect structure 168 includes a combination of vertically-stacked multiple levels of dielectric layers and electrically conductive features formed therein. The dielectric layers may include silicon oxide (SiO), silicon nitride (SiN), silicon oxynitride (SiON), dielectric material(s) with low dielectric constant (low-k) such as SiCOH, SiOCN, SiOC, USG, BPSG, FSG, PSG, BSG, and/or an extreme low-k (ELK) dielectric material with a dielectric constant (k) less than about 3.0.

The conductive features are configured to form vertical interconnect features (providing, for example, vertical connection between features and/or vertical electrical routing), such as vias, and/or horizontal interconnect features (providing, for example, horizontal electrical routing), such as metal lines, in accordance with some embodiments. Vertical conductive features of an interconnect structure typically connect horizontal conductive features in different layers (or different planes) of the multilayer interconnect structure, in accordance with some embodiments. The conductive features may be made of Ta, TaN, Ti, TiN, CoW, Co, Ni, W, Ti, Ta, Cu, Rh, Ir, Pt, Al, Ru, Mo, or a combination thereof. In some embodiments, the frontside interconnect structure 168 may include multiple levels of the metal layer. For example, conductive lines of a first-level metal layer 166 are electrically connected to the vias 162, in accordance with some embodiments.

FIGS. 2I-1 to 2I-3 illustrate the semiconductor structure 100 after flipping the semiconductor structure 100, in accordance with some embodiments.

A bonding dielectric material 169 is formed over the semiconductor structure 100, a carrier substrate 170 is bonded to the frontside surface of the semiconductor structure 100 by dielectric-to-dielectric bonding, for example, and the semiconductor structure 100 (or the semiconductor substrate 102) is flipped upside down, as shown in FIGS. 2I-1 to 2I-3, in accordance with some embodiments. After flipping the semiconductor structure 100, the backside surface of the substrate 102 (or the backside of the semiconductor structure 100) faces upward, in accordance with some embodiments.

In some embodiments, the bonding dielectric material 169 is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), AlN, BN, SiC, BeO, or a combination thereof. In some embodiments, the bonding dielectric material 169 is deposited using CVD (such as LPCVD, PECVD, or HDP-CVD), ALD, another suitable technique, or a combination thereof. In some embodiments, the carrier substrate 170 is a semiconductor substrate, a ceramic substrate, a glass substrate, a polymer substrate, or another suitable substrate.

FIGS. 2J-1 to 2J-3 illustrate the semiconductor structure 100 after removal of at least the bulk of the semiconductor substrate 102, in accordance with some embodiments.

A first planarization process 1000 is performed on the backside surface of the semiconductor structure 100 to remove the substrate 102 from the backside of the semiconductor structure 100 until the backside surface (i.e., the top surfaces in the current schematics) of the isolation structure 110 and the backside surface (i.e., the top surfaces in the current schematics) of the dielectric layer 140 are exposed, as shown in FIGS. 2J-1, 2J-2 and 2J-3, in accordance with some embodiments. In some embodiments, the first planarization process 1000 includes CMP process, a grinding process, an etching process, or a combination thereof. In some embodiments, after the first planarization process 1000, the bulk portion of the isolation structure 110 has a height H1 in a range from about 30 nm to about 100 nm.

In the first planarization process 1000, the lower fin elements 104L are also recessed from the backside of the semiconductor structure 100 thereby forming recesses 172, as shown in FIGS. 2J-2 and 2J-3, in accordance with some embodiments. For example, in order to completely remove the bulk substrate 102 from the backside surface of the isolation structure 110, the CMP process and/or etching process for the first planarization process 1000 may also etch the lower fin elements 104L, causing the lower fin elements 104L to be depressed after the isolation structure 110 is exposed, because the lower fin elements 104L and the substrate 102 are made of the same semiconductor material (e.g., Si). As a result, the backside of the semiconductor structure 100 has an uneven surface topography.

The recesses 172 partially expose the side surfaces of the isolation structure 110, in accordance with some embodiments. In some embodiments, the exposed backside surfaces (i.e., the top surfaces in the current schematics) of the lower fin elements 104L are lower than the backside surfaces (i.e., the top surfaces in the current schematics) of the conductive feature 142, and higher than backside surfaces (i.e., the top surfaces in the current schematics) of the final gate stacks 128. In some embodiments, the aspect ratio, defended as depth D divided by width W, of the recess 172 is in a range from about 1 to about 5. If the aspect ratio is too large, a void may be formed within a subsequently formed metal material in the recess 172. In a subsequent planarization process, the metal material in the recess 172 and the underlying lower fin element 104L may be lost.

FIGS. 2K-1 to 2K-3 illustrate the semiconductor structure 100 after the deposition of a metal material 174, in accordance with some embodiments.

A metal material 174 is formed over the backside surfaces of the isolation structure 110 and the lower fin element 104L, as shown in FIGS. 2K-1 to 2K-3, in accordance with some embodiments. The recesses 172 are overfilled by the metal material 174, in accordance with some embodiments. The metal material 174 is configured as a planarization material, which may reduce the unevenness of the surface topography to facilitate a subsequent planarization process. The metal material 174 may also be referred to as CMP overburn material.

The metal material 174 is deposited using CVD, PVD, e-beam evaporation, ALD, electroplating (ECP), electroless deposition (ELD), another suitable method, or a combination thereof to overfill the contact openings. The metal material 174 may be molybdenum (Mo), ruthenium (Ru), tungsten (W), cobalt (Co), nickel (Ni), titanium (Ti), tantalum (Ta), copper (Cu), rhodium (Rh), iridium (Ir), platinum (Pt), aluminum (Al), another suitable metal material, or a combination thereof. In some embodiments, the metal material 174 has a resistivity less than 60 μΩ·cm. In some embodiments, the metal material 174 has a thickness T over the isolation structure 110, and the thickness T may be in a range from about 50 nm to about 200 nm.

FIGS. 2L-1 to 2M-3 illustrate a second planarization process (including steps 1050A and 1050B), in accordance with some embodiments.

A second planarization process is performed on the semiconductor structure 100 from the backside of the semiconductor structure 100 to thin down the isolation structure 110, the lower fin element 104L and the conductive feature 142 to a desired height, in accordance with some embodiments. The second planarization process is a chemical mechanical polishing process, and includes a first polishing step 1050A (illustrated in FIGS. 2L-1 to 2L-3), and a second polishing step 1050B (illustrated in FIGS. 2M-1 to 2M-3), in accordance with some embodiments.

The first polishing step 1050A and the second polishing step 1050B may be consecutively performed in different chambers of the same CMP tool, which may prevent metal from the conductive features 142 and the metal material 174 from being oxidized due to exposure to an oxygen-containing atmosphere. In some embodiments, the first polishing step 1050A has a relatively high removal rate to efficiently remove the metal material 174, while the second polishing step 1050B has a relatively low removal rate to precisely control the final heights of the isolation structure 110, the lower fin element 104L and the conductive feature 142.

In the first polishing step 1050A, the metal material 174 is polished away until the backside surface of the isolation structure 110, as shown in FIGS. 2L-1 to 2L-3, in accordance with some embodiments. The first polishing step 1050A is performed with end-point mode, and is completed or stopped once the signal of the end-point (such as a large change in polishing pressure) is detected, in accordance with some embodiments. In some embodiments, the isolation structure 110 is configured as a polishing stop layer in the first polishing step 1050A to provide the signal (e.g., changes in polishing pressure or removal rate) of the end-point when the isolation structure 110 is being polished.

In some embodiments, the removal rate of the metal material 174 in the first polishing step 1050A is much greater than the removal rate of the isolation structure 110 in the first polishing step 1050A. For example, the removal rate of the metal material 174 is greater than 1000 Å/min, and the removal rate of the isolation structure 110 is less than 10 Å/min. After the first polishing step 1050A is completed, the backside surface of the remaining metal material 174′ in the recess 172 is substantially level with the backside surface of the isolation structure 110 and the backside surface of the dielectric layer 140, in accordance with some embodiments.

The first polishing step 1050A uses the slurry for metal, which may include an abrasive dispensed in a liquid carrier. The abrasives may be configured to provide mechanical polishing effect during the CMP operation. The abrasives may include inorganic particles such as silicon oxide-based (silica-based) particles, or another suitable abrasive. The liquid carrier may include water or other solvents. In some embodiments, the concentration of the abrasives is greater than 0.1 wt %. In some embodiments, the slurry for the first polishing step 1050A may further include an oxidizer. The oxidizer may be configured to oxidize the metal material 174. The oxidized metal material 174 is easily removed by mechanical polishing force. The oxidizer may include, but is not limited to, a peroxide, a halogenoxy acid, a salt of halogenoxy acid, a persulfate, a perborate, a periodate or mixtures thereof. In some embodiments, the slurry may further include a corrosion inhibitor to inhibit corrosion of the remaining metal material 174 and conductive features 142 (if the dielectric layer 140 is broken through) during the first polishing step 1050A. The slurry used in the first polishing step 1050A may also be referred to as a bulk metal slurry.

In the second polishing step 1050B, the remaining metal material 174′, the isolation structure 110, and the dielectric layer 140 are first polished to expose the conductive structure 142; the conductive structure 142 is then polished together with the metal material 174′, the isolation structure 110 and the dielectric layer 140 to expose the lower fin element 104L, and finally, the fin element 104L is polished together with the conductive structure 142, the isolation structure 110, and the dielectric layer 140 to a specified level, in accordance with some embodiments.

The second polishing step 1050B is performed with time mode, and the time period of the second polishing step 1050B is determined by the time period required for the lower fin element 104L, the isolation structure 110, and the conductive feature 142 reaching the specified level. In the second polishing step 1050B, there is no polishing selectivity or extremely low polishing selectivity among all materials. That is, the removal rates of metal material, dielectric material and semiconductor material may be controlled to be substantially the same. For example, the removal rates of the metal material 174′, the isolation structure 110, the dielectric layer 140, the conductive feature 142 and the lower fin element 104L are substantially the same.

The second polishing step 1050B is performed at a removal rate that is much lower than the removal rate of the first polishing step 1050A, thereby precisely controlling the final heights of the isolation structure 110, the lower fin element 104L and the conductive feature 142. In some embodiments, the removal rate of the remaining metal material 174′ and the conductive feature 142 (made of metal material) in the second polishing step 1050B is lower than the removal rate of the metal material 174 in the first polishing step 1050A.

As a result, the polished surfaces of all materials may be continued to remain substantially leveled during the second polishing step 1050B. After the second polishing step 1050B, the backside surface of the isolation structure 110, the backside surface of the dielectric layer 140, the backside surface of the conductive feature 142 and the backside surface of the lower fin element 104L are substantially level with each other, in accordance with some embodiments. That is, the step height between adjacent components (e.g., between the conductive feature 142, the isolation structure 110 and the lower fin element 104L) is substantially equal to zero.

The second polishing step 1050B uses the slurry for metal, dielectric and poly-silicon, which may include an abrasive dispensed in a liquid carrier. The abrasives may include inorganic particles such as silicon oxide-based (silica-based) particles, cerium oxide particles, another suitable abrasive, or a combination thereof. The liquid carrier may include water or other solvents. In some embodiments, the slurry may further include a corrosion inhibitor to inhibit corrosion of the metal material 174′ and the conductive features 142 during the second polishing step 1050B. The slurry used in the second polishing step 1050A may also be referred to as buffer slurry.

In the embodiments of the present disclosure, the metal material 174 is used as CMP overburn material instead of using a non-metallic material such as dielectric material (e.g., silicon oxide) or semiconductor material (e.g., poly-silicon). The first polishing step 1050A may be precisely stopped when the backside surface of the isolation structure 110 is exposed because of the high polishing selectivity between the metal material and dielectric material (e.g., silicon oxide).

In the case where a non-metallic material (e.g., SiO) is used as CMP overburn material, the first polishing step may be performed to remove the CMP overburn material and the underlying isolation structure, both of which are made of dielectric material, until the fin element (e.g., made of Si) is exposed. As a result, the conductive feature 142 may protrude from the isolation structure 110 due to the low removal rate of the metal material in the first polishing step. Therefore, the backside surface of the semiconductor structure may have an uneven surface topography after the first poling step, and may maintain this topography after the second polishing step. Such an uneven surface topography may cause pool coating or peeling of subsequently deposited layers, thereby negatively affecting the manufacturing yield and reliability of the resulting semiconductor device.

In the embodiments of the present disclosure, the backside surface of the semiconductor structure 100 remains substantially flat during the entire second planarization process. Therefore, the backside of the semiconductor structure 100 may have substantially flat topography, so that the pool coating or peeling problems may be alleviated or avoided. Therefore, the manufacturing yield and reliability of the resulting semiconductor device may be improved.

In addition, the second planarization process includes the first polishing step 1050A with a relatively high removal rate and the second polishing step 1050B with a relatively low removal rate, and thus a good balance between the process efficiency and accuracy may be achieved. Therefore, the manufacturing yield and performance of the resulting semiconductor device may be improved.

In some embodiments, after the second planarization process, the bulk portion of the isolation structure 110 has a height H1′ less than about 50 nm. The lower fin element 104L has a height H2 in a range from about 20 nm to about 60 nm. In some embodiments, a distance D1 between the backside surface of the conductive feature 142 and the first interlayer dielectric layer 126B is in a range from about 10 nm to about 50 nm. If the distance D1 is too small, the risk of a leakage path between the conductive feature 142 and the bottom source/drain feature 122B may increase. In some embodiments, the conductive feature 142 has a dimension D2 in the X direction and a dimension D3 in the Y direction. The dimension D2 is in a range from about 50 nm to 100 nm, and the dimension D3 is less than 50 nm.

FIGS. 2N to 2N-4 illustrate the semiconductor structure 100 after the deposition of the fourth interlayer dielectric layer 176 and the backside contact structure 178, in accordance with some embodiments.

A fourth interlayer dielectric layer 176 is formed over the semiconductor structure 100, as shown in FIGS. 2N-1 to 2N-4, in accordance with some embodiments. In some embodiments, the material of the fourth interlayer dielectric layer 176 may be the same as or similar to the material of the first interlayer dielectric layer 126B.

A backside contact structure 178 is formed on the backside surface of the bottom source/drain features 122B, as shown in FIGS. 2N-2 and 2N-4, in accordance with some embodiments. The contact structure 178 penetrates through the fourth interlayer dielectric layer 176, the lower fin element 104L, and lands on and is electrically connected to the bottom source/drain features 122B, in accordance with some embodiments.

The backside contact structure 178 further penetrates through the isolation structure 110, the dielectric layer 140, and lands on and is electrically connected to the conductive feature 142, in accordance with some embodiments. As a result, the backside contact structure 178 is electrically connected to the frontside contact structure 150A through the conductive feature 142, in accordance with some embodiments. In some embodiments, the insulating feature 144 vertically overlaps the backside contact structure 178. In some embodiments, the backside contact structure 178 and the bottom source/drain feature 122B connected thereto are used for a non-Vdd/Vss node (e.g., a drain terminal).

In some embodiments, the formation of the contact structure 178 includes patterning the semiconductor structure 100 to form a contact opening (where the contact structure 178 is to be formed) using one or more photolithography and etching processes to expose the source/drain features 122B and the conductive features 142. The etching process may include dry etching such as RIE, NBE, ICP etch, CCP etch, another suitable method, or a combination thereof.

A silicide layer 180 is formed on the exposed surface of the source/drain feature 122B. In some embodiments, the silicide layers 180 are made of WSi, NiSi, TiSi and/or CoSi. Afterward, one or more conductive materials for the contact structures 180 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 148 are planarized using, for example, CMP.

For example, a barrier/adhesive layer 182 may optionally be deposited along the sidewalls and the bottom surfaces of the contact openings. The barrier/adhesive layer 156 may be made of tantalum (Ta), tantalum nitride (TaN), titanium (Ti), titanium nitride (TiN), cobalt tungsten (CoW), another suitable material, or a combination thereof. A metal bulk layer of the contact structures 180 is then deposited on the barrier/adhesive layer 182 (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

It should be understood that the semiconductor structure 100 may undergo further CMOS processes to form various features over the semiconductor structure 100, such as a multilayer interconnect structure (e.g., backside metal lines, inter metal dielectric layers, passivation layers, etc.).

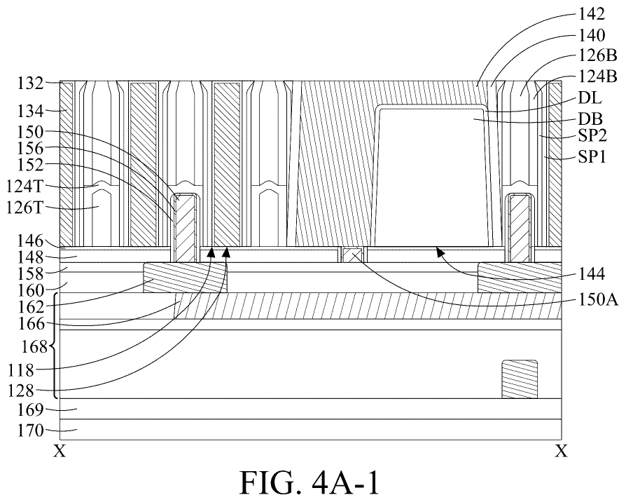

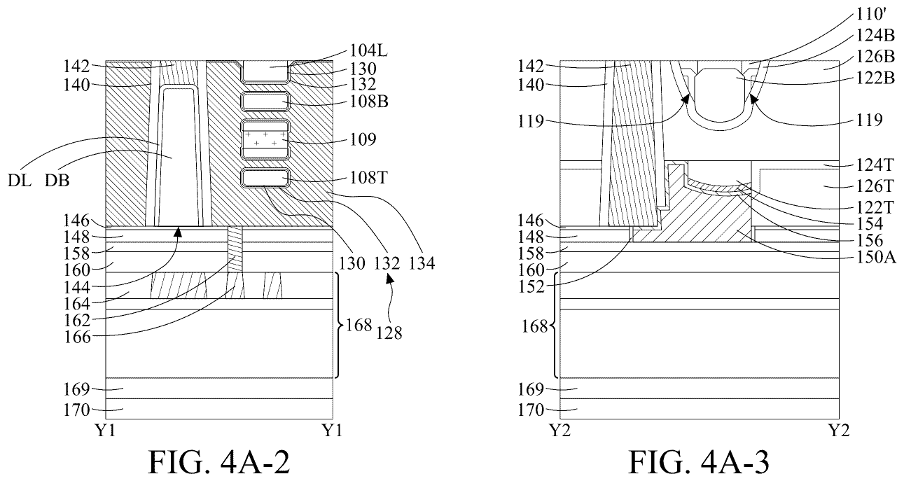

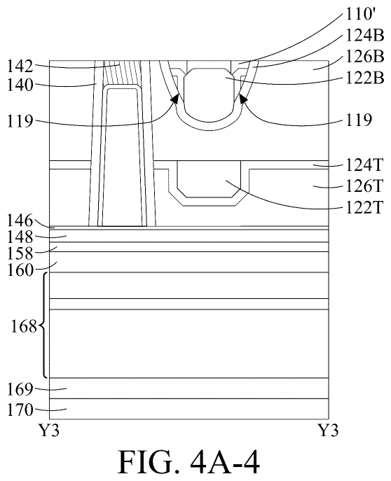

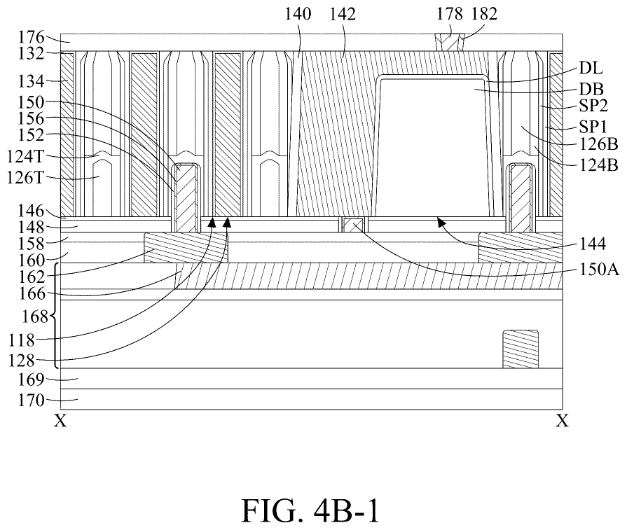

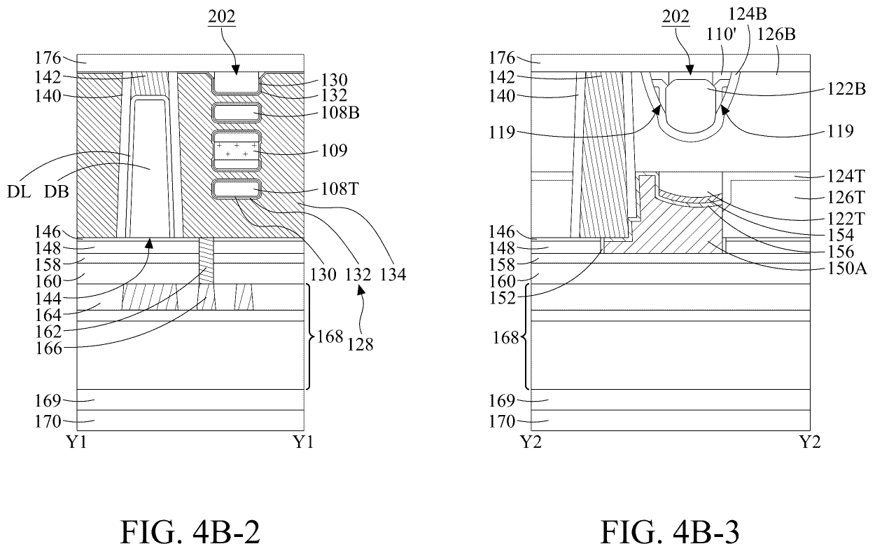

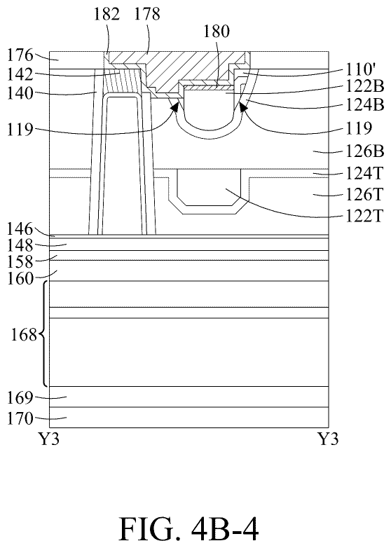

FIGS. 3A-1 through 3B-4 are cross-sectional views illustrating the formation of the semiconductor structure at various intermediate stages, in accordance with some embodiments of the disclosure. FIGS. 3A-1 and 3B-1 correspond to line X-X of FIG. 2. FIGS. 3A-2 and 3B-2 correspond to line Y1-Y1 of FIG. 2. FIGS. 3A-3 and 3B-3 correspond to line Y2-Y2 of FIG. 2. FIGS. 3A-4 and 3B-4 correspond to line Y3-Y3 of FIG. 2. The embodiments of FIGS. 3A-1 to 3B-2 are similar to the embodiments of FIGS. 2A to 2N-4 where like reference numerals indicate like elements formed by like processes except that the lower fin elements 104L are replaced with dielectric elements 204.

Continuing from FIGS. 2M-1 to 2M-3, the lower fin elements 104L are removed using an etching process, thereby forming openings 202, as shown in FIGS. 3A-1 to 3A-4, in accordance with some embodiments. The openings 202 expose the interfacial layer 130 of the final gate stacks 128 and the source/drain features 122B, in accordance with some embodiments. In some embodiments, the etching process includes plasma dry etching, a dry chemical etching, and/or a wet etching.

Dielectric fin elements 204 are formed in the openings 202, as shown in FIGS. 3B-1 to 3B-4, in accordance with some embodiments. Afterward, the backside contact structure 178 is formed on the backside surface of the bottom source/drain features 122B, in accordance with some embodiments. In some embodiments, the dielectric fin elements 204 are made of dielectric material, such as silicon oxide (SiO₂), silicon nitride (SiN), silicon oxynitride (SiON), oxygen-doped silicon carbide (SiC:O), oxygen-doped silicon carbonitride (Si(O)CN), silicon carbide (SiC), or another suitable dielectric material.

The formation of the dielectric fin elements 204 includes depositing dielectric material to fill the openings 202 using ALD, CVD (such as LPCVD, PECVD or HDP-CVD or a combination thereof, and performing a planarization process to remove the dielectric material from the backside surface of the isolation structure 110, in accordance with some embodiments. The planarization process may be a CMP or an etching back process. In some embodiments, after the planarization process, the backside surface of the isolation structure 110, the backside surface of the dielectric layer 140, the backside surface of the conductive feature 142 and the backside surfaces of the dielectric fin elements 204 are substantially level with each other, in accordance with some embodiments.

The formation of the dielectric fin elements 204 may reduce the overall cell capacitance of the CFET device. In addition, the risk of leakage caused by the planar transistor being formed from the lower fin element 104L may be reduced. Therefore, the performance of the resulting semiconductor device may be enhanced, e.g., faster speed, lower power consumption, and/or lower off-state current.

FIGS. 4A-1 through 4B-4 are cross-sectional views illustrating the formation of the semiconductor structure at various intermediate stages, in accordance with some embodiments of the disclosure. FIGS. 4A-1 and 4B-1 correspond to line X-X of FIG. 2. FIGS. 4A-2 and 4B-2 correspond to line Y1-Y1 of FIG. 2. FIGS. 4A-3 and 4B-3 correspond to line Y2-Y2 of FIG. 2. FIGS. 4A-4 and 4B-4 correspond to line Y3-Y3 of FIG. 2. The embodiments of FIGS. 4A-1 to 4B-2 are similar to the embodiments of FIGS. 2A to 2N-4 where like reference numerals indicate like elements formed by like processes except that the bulk portion of the isolation structure 110 is removed.

In the second polishing step 1050B, the remaining metal material 174′, the isolation structure 110, the dielectric layer 140, the conductive feature 142 and the lower fin element 104L are polished away until the gate dielectric layer 132 of the final gate stacks 128 is exposed, as shown in FIGS. 4A-1 to 4A-4, in accordance with some embodiments. The contact etching stop layer 124B and the first interlayer dielectric layer 126B are also polished, in accordance with some embodiments. As a result, the bulk portion of the isolation structure 110 is removed, and the portion of the isolation structure 110 alongside the lower fin element 104L remains and is denoted as 110′, in accordance with some embodiments.

In some embodiments, after the second planarization process, the backside surface of the remaining isolation structure 110′, the backside surface of the dielectric layer 140, the backside surface of the conductive feature 142, the backside surface of the lower fin element 104L, the backside surface of the first interlayer dielectric layer 126B, and the backside surface of the gate dielectric layer 132 are substantially level with each other, in accordance with some embodiments. Afterward, the backside contact structure 178 is formed on the backside surface of the bottom source/drain features 122B, as shown in FIG. 4B-4, in accordance with some embodiments.

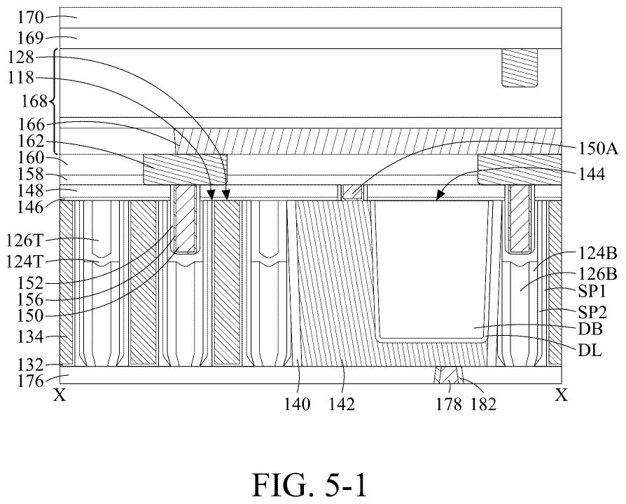

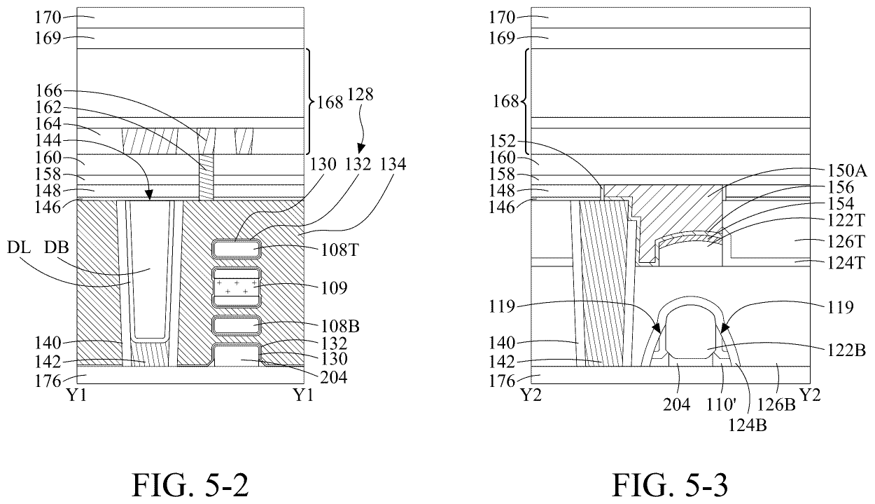

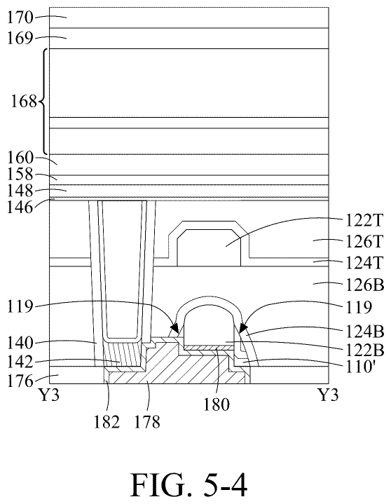

FIGS. 5-1, 5-2, 5-3 and 5-4 are a modification of the semiconductor structure 100 of FIG. 4N-1, 4N-2, 4N-3 and 4N-4, in accordance with some embodiments of the disclosure. The embodiments of FIGS. 5-1 to 5-2 are similar to the embodiments of FIGS. 4N-1 to 4N-4 where like reference numerals indicate like elements formed by like processes except that the lower fin elements 104L are replaced with dielectric features 204.

After the second polishing step 1050B, the lower fin elements 104L are removed using an etching process, thereby forming openings, and then dielectric fin elements 204 are formed in the openings 202, as shown in FIGS. 5-1 to 5-4, in accordance with some embodiments. Afterward, the backside contact structure 178 is formed on the backside surface of the bottom source/drain features 122B, in accordance with some embodiments. The formation and the material of the dielectric fin elements 204 may be the same as or similar to the description above in FIGS. 3B-1 to 3B-4.

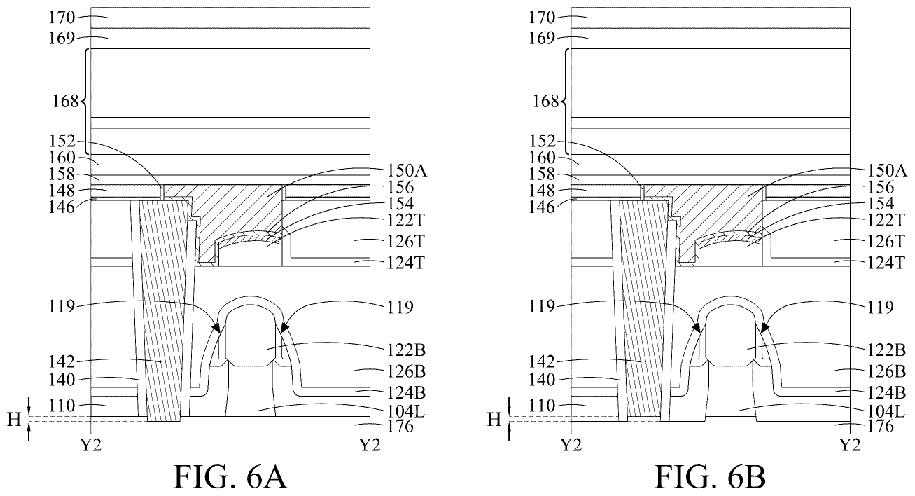

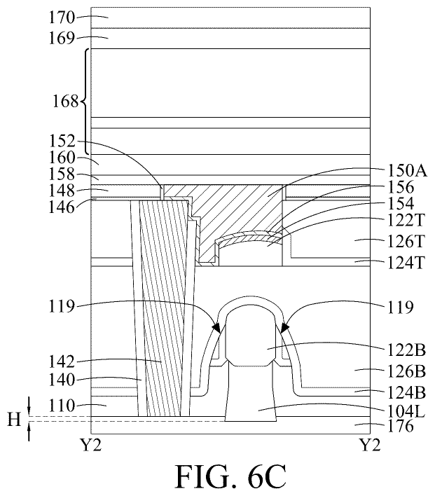

FIGS. 6A, 6B and 6C are various modifications of the semiconductor structure 100 of FIG. 2N-3, in accordance with some embodiments of the disclosure. The embodiments of FIGS. 6A, 6B and 6C are similar to the embodiments of FIGS. 2A to 2N-4 where like reference numerals indicate like elements formed by like processes except that a step height H is formed in the second polishing step 1050B of the second planarization process because of adjustment of the parameters of the second polishing step 1050B, e.g., types and/or concentrations of abrasives, chemicals and/or solvents.

In some embodiments, the removal rate of the conductive feature 142 is slightly lower than the removal rate of the isolation structure 110 and the removal rate the lower fin element 104L in the second polishing step 1050B, and thus the backside surface of conductive feature 142 is higher than the backside surface of the isolation structure 110 and the top surface of the lower fin element 104L (when the backside of the semiconductor structure 100 faces upward), as shown in FIG. 6A.

In some embodiments, the removal rate of the isolation structure 110 is slightly lower than the removal rate of the conductive feature 142 and the removal rate the lower fin element 104L in the second polishing step 1050B, and thus the backside surface of the isolation structure 110 is higher than the backside surface of the conductive feature 142 and the top surface of the lower fin element 104L (when the backside of the semiconductor structure 100 faces upward), as shown in FIG. 6B.

In some embodiments, the removal rate of the lower fin element 104L is slightly lower than the removal rate of the conductive feature 142 and the removal rate the isolation structure 110 in the second polishing step 1050B, and thus the backside surface of the lower fin element 104L is higher than the backside surface of the conductive feature 142 and the top surface of the isolation structure 110 (when the backside of the semiconductor structure 100 faces upward), as shown in FIG. 6C.

In the embodiments of the present disclosure, because the difference in the removal rate between the metal material, the dielectric material and the semiconductor material in the second polishing step 1050B is much lower than the difference in the removal rate between the metal material, the dielectric material and the semiconductor material in the first polishing step 1050A, the step height H can be much lower than the protrusion of the conductive feature discussed above, and may reduce pool coating or peeling of subsequently deposited layers. In some embodiments, the step height H is approximately 1/70 times the height of the protrusion.

As described above, the semiconductor structure 100 includes CFET devices and a conductive feature 142 electrically connected to the source/drain terminal of the top transistor TT and the source/drain terminal of the bottom transistor BT. The embodiments utilize the metal material 174 as a CMP overburn material in the second planarization process of the wafer bonding stage. Due to high polishing selectivity between the metal material 174 and the isolation structure 110, the first polishing step 1050A of the second planarization process may be stopped when the backside surface of the isolation structure 110 is exposed, which may prevent the protrusion of the conductive feature 142 from the isolation structure 110. Therefore, the backside of the semiconductor structure 100 may maintain a substantially flat surface topography after the second polishing step 1050B of the second planarization process, and thus the manufacturing yield and reliability of the resulting semiconductor device may be improved.

Embodiments of a semiconductor structure and the method for forming the same may be provided. The method for forming a CET device includes forming a conductive feature between active regions and across gate stacks, removing the substrate to expose the isolation structure, depositing a metal material over the isolation structure, planarizing the metal material until the isolation structure is exposed, and planarizing the metal material, isolation structure and the fin element to a specific level. Therefore, the backside of the semiconductor structure may maintain a substantially flat surface topography, and thus the manufacturing yield and reliability of the resulting semiconductor device may be improved.

In some embodiments, a method for forming a semiconductor structure is provided. The method includes forming an isolation structure to surround a lower portion of an active region, forming a gate stack across the active region, forming a trench through the gate stack, forming a conductive feature in the trench, depositing a metal material on a backside surface of the isolation structure, and planarizing the metal material, the isolation structure, the conductive feature, and the lower portion of the active region.

In some embodiments, a method for forming a semiconductor structure is provided. The method includes forming a first active region and a second active region over a substrate. Each of the first active region and the second active region includes a fin element and nanostructures over the fin element. The method further includes forming an isolation structure to surround the fin elements of the first active region and the second active region, forming a plurality of gate stacks to surround the nanostructures of the first active region and the second active region, forming a conductive feature between the first active region and the second active region and across the plurality of gate stacks, and planarizing the substrate until the isolation structure is exposed. A recess is formed in the fin elements of the first active region and the second active region during the planarization of the substrate, depositing a metal material over the isolation structure to fill the recesses, and planarizing the metal material until the isolation structure is exposed.

In some embodiments, a semiconductor structure is provided. The semiconductor structure includes a first nanostructure above a fin element, a second nanostructure above the first nanostructure, a gate stack surrounding the first nanostructure and the second nanostructure, a first source/drain feature adjoining the first nanostructure, a second source/drain feature adjoining the second nanostructure, and a conductive feature across the gate stack and electrically connected to the second source/drain feature. A backside surface of the conductive feature is substantially level with a backside surface of the fin element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, the method comprising:
forming an isolation structure surrounding a lower portion of an active region;
forming a gate stack across the active region;
forming a trench through the gate stack;
forming a conductive feature in the trench;
depositing a metal material on a backside surface of the isolation structure; and
planarizing the metal material, the isolation structure, the conductive feature, and the lower portion of the active region.

2. The method for forming the semiconductor structure according to claim 1, further comprising:
forming the active region over a substrate;
flipping the substrate upside down; and
removing the substrate to expose the backside surface of the isolation structure prior to depositing the metal material.

3. The method for forming the semiconductor structure according to claim 2, wherein the lower portion of the active region is recessed to form a recess while removing the substrate, and the metal material fills the recess.

4. The method for forming the semiconductor structure according to claim 1, wherein planarizing the metal material, the isolation structure, the conductive feature, and the lower portion of the active region comprises:
a first step comprising polishing the metal material using a first slurry until the backside surface of the isolation structure is exposed; and
a second step comprising polishing the conductive feature, the isolation structure and the lower portion of the active region using a second slurry that is different than the first slurry.

5. The method for forming the semiconductor structure according to claim 4, wherein a removal rate of the metal material in the first step is greater than a removal rate of the conductive feature in the second step.

6. The method for forming the semiconductor structure according to claim 1, wherein the active region comprises a first channel layer over the lower portion of the active region, and a second channel layer over the first channel layer, and the method further comprises:
forming a first source/drain feature adjoining the first channel layer;
forming a second source/drain feature adjoining the second channel layer, the second source/drain feature overlapping the first source/drain feature; and
forming a first contact structure on a frontside surface of the second source/drain feature and a frontside surface of the conductive feature.

7. The method for forming the semiconductor structure according to claim 6, further comprising:
forming a third source/drain feature adjoining the first channel layer;
forming a fourth source/drain feature adjoining the second channel layer; and
forming a second contact structure on a backside surface of the third source/drain feature and a backside surface of the conductive feature.

8. The method for forming the semiconductor structure according to claim 6, wherein the first source/drain feature is doped with a first dopant having a first conductivity type, and the second source/drain feature is doped with a second dopant having a second conductivity type that is the opposite of the first conductivity type.

9. The method for forming the semiconductor structure according to claim 1, further comprising:
removing the lower portion of the active region to form an opening; and
depositing a dielectric material in the opening.

10. A method for forming a semiconductor structure, comprising:
forming a first active region and a second active region over a substrate, wherein each of the first active region and the second active region includes a fin element and nanostructures over the fin element;
forming an isolation structure surrounding the fin elements of the first active region and the second active region;
forming a plurality of gate stacks surrounding the nanostructures of the first active region and the second active region;
forming a conductive feature between the first active region and the second active region and across the plurality of gate stacks;
planarizing the substrate until the isolation structure is exposed, wherein a recess is formed in a fin element of the first active region while planarizing the substrate;
depositing a metal material over the isolation structure to fill the recesses; and
planarizing the metal material until the isolation structure is exposed.

11. The method for forming the semiconductor structure according to claim 10, wherein a top surface of the metal material and a top surface of the isolation structure are at a same level after planarizing the metal material.

12. The method for forming the semiconductor structure according to claim 10, further comprising:
planarizing the isolation structure, the conductive feature and the fin elements of the first active region and the second active region after planarizing the metal material.

13. The method for forming the semiconductor structure according to claim 12, wherein the isolation structure, the conductive feature and the fin elements of the first active region and the second active region are planarized until the gate stacks are exposed.

14. The method for forming the semiconductor structure as claimed in claim 12, wherein after planarizing the isolation structure, the conductive feature and the fin elements of the first active region and the second active region, a backside surface of the isolation structure is at a different level than a backside surface of the conductive feature.

15. A semiconductor structure, comprising:
a first nanostructure above a fin element;
a second nanostructure above the first nanostructure;
a gate stack surrounding the first nanostructure and the second nanostructure;
a first source/drain feature adjoining the first nanostructure;
a second source/drain feature adjoining the second nanostructure, the first source/drain feature overlapping the second source/drain feature; and
a conductive feature across the gate stack and electrically connected to the second source/drain feature, wherein a backside surface of the conductive feature is substantially level with a backside surface of the fin element.

16. The semiconductor structure as claimed in claim 15, wherein a frontside surface of the conductive feature is substantially level with a frontside surface of the gate stack.

17. The semiconductor structure as claimed in claim 15, further comprising:
a dielectric layer separating the first source/drain feature from the second source/drain feature.

18. The semiconductor structure as claimed in claim 15, further comprising:
a contact structure on the second source/drain feature and the conductive feature.

19. The semiconductor structure as claimed in claim 15, wherein the fin element is made of a dielectric material.

20. The semiconductor structure as claimed in claim 15, further comprising:
an isolation structure surrounding the fin element, wherein the backside surface of the conductive feature is substantially level with a backside surface of the isolation structure.
